(19) United States
(12) Patent Application Publication
(10) Pub. No.: US 2026/0231394 A1
(43) Pub. Date: Aug. 6, 2026

(54) SEMICONDUCTOR DEVICE INCLUDING A CAPACITOR STRUCTURE AND METHOD OF MANUFACTURING THE SAME

(71) Applicant: Samsung Electronics Co., Ltd., Suwon-si (KR)

(72) Inventors: Seongtak Cho, Suwon-si (KR); Donghyung Kim, Suwon-si (KR); Yongkwan Kim, Suwon-si (KR); Inwoo Kim, Suwon-si (KR); Huijung Kim, Suwon-si (KR); Gyusoup Lee, Suwon-si (KR); Sangho Lee, Suwon-si (KR); Hongjun Lee, Suwon-si (KR)

(21) Appl. No.: 19/464,019

(22) Filed: Jan. 29, 2026

(30) Foreign Application Priority Data
Feb. 6, 2025 (KR) 10-2025-0015360

(51) Int. Cl. H10B 12/00

(52) U.S. Cl. CPC H10B 12/315; H10B 12/033

(57) ABSTRACT

A semiconductor device includes a first electrode layer on a substrate and including a first main electrode portion and a first electrode top portion on the first main electrode portion with a step defined therebetween, a second electrode layer on the first electrode layer, a conductive skin layer on a first portion of a side wall of the first electrode top portion, an insulating skin layer on a second portion of the side wall of the first electrode top portion, a supporter pattern on a side wall of the insulating skin layer and a side wall of the conductive skin layer, a capacitor dielectric layer on a side wall of the first electrode layer and a side wall of the second electrode layer, and an upper electrode on the capacitor dielectric layer.

### CROSS-REFERENCE TO RELATED APPLICATION

This application is based on and claims priority under 35 U.S.C. §119 to Korean Patent Application No. 10-2025-0015360, filed on February 6, 2025, in the Korean Intellectual Property Office, the disclosure of which is incorporated by reference herein in its entirety.

### BACKGROUND

With the downscaling of semiconductor devices, the size of capacitor structures included in semiconductor devices has also been reduced. Accordingly, there is a demand for the development of devices that may have improved capacitance and excellent electrical characteristics even when the size of capacitor structures is reduced.

### SUMMARY

Aspects of the present disclosure relate to a semiconductor device and a method of manufacturing the same, and more specifically, to a semiconductor device including a capacitor structure and a method of manufacturing the same. For example, aspects of the present disclosure may provide a semiconductor device including a lower electrode that has a relatively large height and prevent a bridge defect between lower electrodes even when a distance between the lower electrodes is relatively small.

Aspects of the present disclosure provide a method of manufacturing a semiconductor device, capable of forming a lower electrode that has a relatively large height and prevent a bridge defect between lower electrodes even when a distance between the lower electrodes is relatively small.

According to an aspect of the present disclosure, a semiconductor device includes a first electrode layer on a substrate and including a first main electrode portion extending in a first direction perpendicular to a top surface of the substrate and a first electrode top portion that is on the first main electrode portion with a step defined therebetween and is connected to the first main electrode portion, a second electrode layer on the first electrode layer and extending in the first direction, an insulating skin layer on a first portion of a side wall of the first electrode top portion and being in contact with a top surface of the first main electrode portion, a supporter pattern on a side wall of the insulating skin layer, a capacitor dielectric layer on a side wall of the first electrode layer and a side wall of the second electrode layer, and an upper electrode on the capacitor dielectric layer.

According to another aspect of the present disclosure, a semiconductor device includes a first electrode layer on a substrate and extending in a first direction perpendicular to a top surface of the substrate, a second electrode layer on the first electrode layer and extending in the first direction, a supporter pattern disposed outside a periphery of an upper side of the first electrode layer and having a top surface at a same level as a top surface of the first electrode layer, a conductive skin layer disposed between a first portion of an upper side wall of the first electrode layer and the supporter pattern and being in contact with a bottom surface of the second electrode layer, an insulating skin layer disposed between a second portion of the upper side wall of the first electrode layer and the supporter pattern, a capacitor dielectric layer on a side wall of the first electrode layer and a side wall of the second electrode layer, and an upper electrode on the capacitor dielectric layer.

According to another aspect of the present disclosure, a semiconductor device includes a plurality of lower electrodes on a substrate, a capacitor dielectric layer on side walls of the plurality of lower electrodes, and an upper electrode on the capacitor dielectric layer, wherein each of the plurality of lower electrodes includes a first electrode layer including a first main electrode portion extending in a first direction perpendicular to a top surface of the substrate and a first electrode top portion that is on the first main electrode portion with a step defined therebetween and is integrally connected to the first main electrode portion, a second electrode layer on the first electrode layer and extending in the first direction, and an insulating skin layer on a first portion of a side wall of the first electrode top portion and being in contact with a top surface of the first main electrode portion, wherein the top surface of the first main electrode portion has a first width in a horizontal direction, a bottom surface of the first electrode top portion has a second width that is less than the first width in the horizontal direction, and the step is defined between an edge of the top surface of the first main electrode portion and the side wall of the first electrode top portion.

In some implementations, a bottom surface of the conductive skin layer may be coplanar with a bottom surface of the insulating skin layer.

In some implementations, the top surface of the first main electrode portion may have a first width in a horizontal direction, a bottom surface of the first electrode top portion may have a second width that is less than the first width in the horizontal direction, and the step may be defined between an edge of the top surface of the first main electrode portion and the side wall of the first electrode top portion.

In some implementations, a bottom portion of the second electrode layer may be integrally connected to the conductive skin layer.

In some implementations, the extended space may vertically overlap the second vertical hole.

### BRIEF DESCRIPTION OF THE DRAWINGS

Example implementations will be more clearly understood from the following detailed description taken in conjunction with the accompanying drawings.

FIG. 1 is a schematic view illustrating a semiconductor device according to some implementations.

FIG. 2 is a layout diagram illustrating a partial configuration of a semiconductor device according to some implementations.

FIG. 3 is a plan view illustrating a partial configuration of a semiconductor device according to some implementations.

FIG. 4 is a cross-sectional view taken along a line A-A' of FIG. 3.

FIG. 5 is a cross-sectional view taken along a line B-B' of FIG. 3.

FIG. 6 is an enlarged view of a portion EN of FIG. 4.

FIG. 7 is a planar layout diagram of a lower electrode at a first vertical level of FIG. 4.

FIG. 8 is a cross-sectional view illustrating a semiconductor device according to some implementations.

FIG. 9 is an enlarged view of a portion EN of FIG. 8.

FIG. 10 is a cross-sectional view illustrating a semiconductor device according to some implementations.

FIG. 11 is an enlarged view of a portion EN of FIG. 10.

FIG. 12 is a cross-sectional view illustrating a semiconductor device according to some implementations.

FIG. 13 is an enlarged view of a portion EN of FIG. 12.

FIG. 14 is a cross-sectional view illustrating a semiconductor device according to some implementations.

FIG. 15 is a cross-sectional view illustrating a semiconductor device according to some implementations.

FIG. 16 is a cross-sectional view illustrating a semiconductor device according to some implementations.

FIGS. 17, 18A, 18B, 19 to 22, 23A, 23B, 24 to 27, 28A, 28B, 28C, and 29 are schematic views illustrating a method of manufacturing a semiconductor device according to a process sequence, according to some implementations.

FIGS. 30 to 36 are cross-sectional views illustrating a method of manufacturing a semiconductor device according to a process sequence, according to some implementations.

FIGS. 37 to 42 are cross-sectional views illustrating a method of manufacturing a semiconductor device according to a process sequence, according to some implementations.

### DETAILED DESCRIPTION OF THE EMBODIMENTS

Hereinafter, some example implementations of the present disclosure will be described in detail with reference to the accompanying drawings.

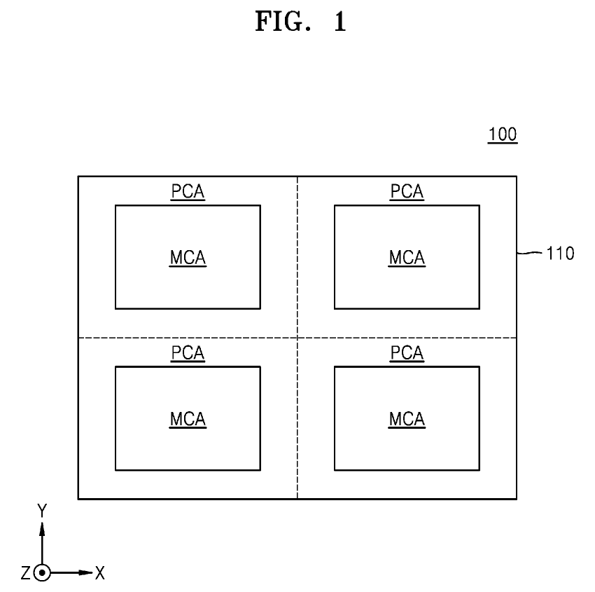

FIG. 1 is a schematic view illustrating a semiconductor device 100 according to some implementations.

Referring to FIG. 1, the semiconductor device 100 may include a cell array area MCA, which is arranged on a substrate 110, and a peripheral circuit area PCA.

In some implementations, the cell array area MCA may be a memory cell area of a DRAM device, and the peripheral circuit area PCA may be a core area or a peripheral circuit area of a DRAM device. For example, the peripheral circuit area PCA may include a peripheral circuit transistor PTR for transmitting a signal and/or power to a memory cell array included in the cell array area MCA. In some implementations, the peripheral circuit transistor PTR may include various circuits such as a command decoder, control logic, an address buffer, a row decoder, a column decoder, a sense amplifier, and a data input/output circuit.

FIG. 1 illustrates that the cell array area MCA and the peripheral circuit area PCA are arranged on the substrate 110 in a horizontal direction, but the present disclosure is not limited thereto. In some implementations, the semiconductor device 100 may include the peripheral circuit area PCA and the cell array area MCA that is arranged at a higher vertical level than the peripheral circuit area PCA. In some implementations, the semiconductor device 100 may include the cell array area MCA and the peripheral circuit area PCA that is arranged at a higher vertical level than the cell array area MCA.

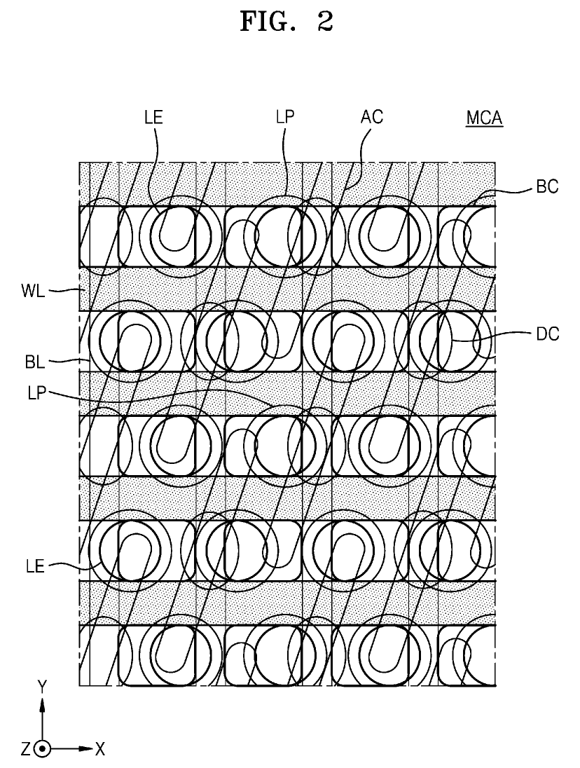

FIG. 2 is a layout diagram illustrating a partial configuration of the semiconductor device 100 according to some implementations.

Referring to FIG. 2, a plurality of active areas AC, each having a relatively long island shape with a short axis and a long axis, may be arranged. A plurality of word lines WL may extend in a first direction (an X direction), across the plurality of active areas AC. A direct contact DC may be arranged on a portion of an active area AC arranged between the plurality of word lines WL, and a plurality of bit lines BL may extend in a second direction (a Y direction) on the direct contact DC. A buried contact BC may be arranged on a portion of the active area AC arranged between the plurality of bit lines BL, and a lower electrode LE may be arranged on the buried contact BC. A landing pad LP may be optionally arranged on the lower electrode LE and the buried contact BC.

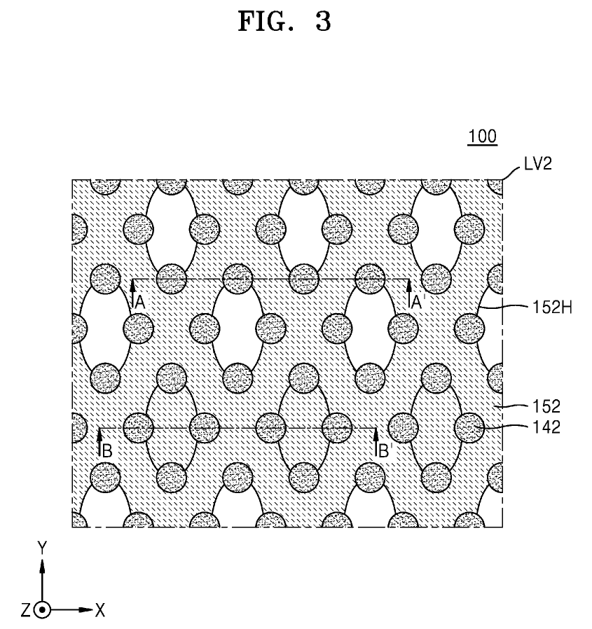

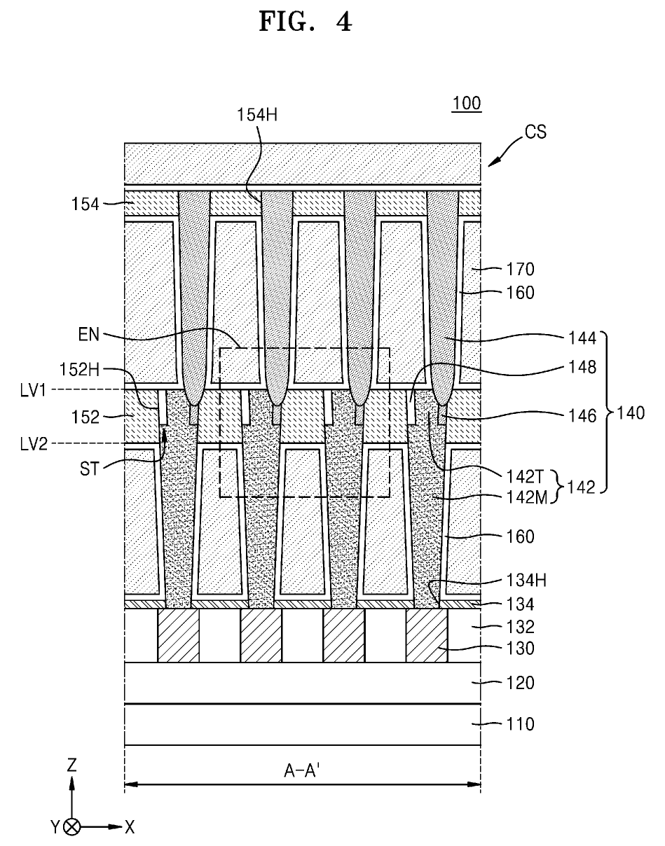

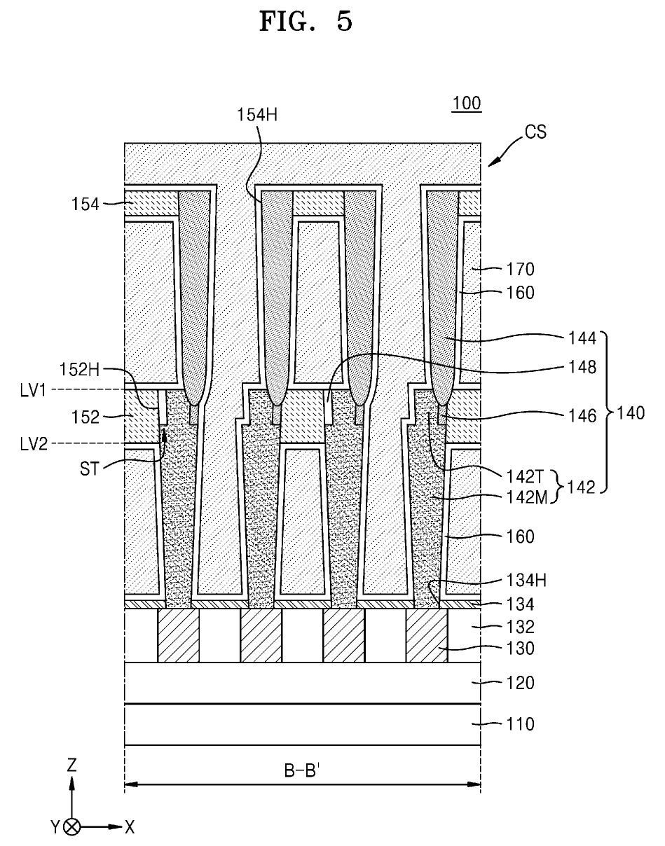

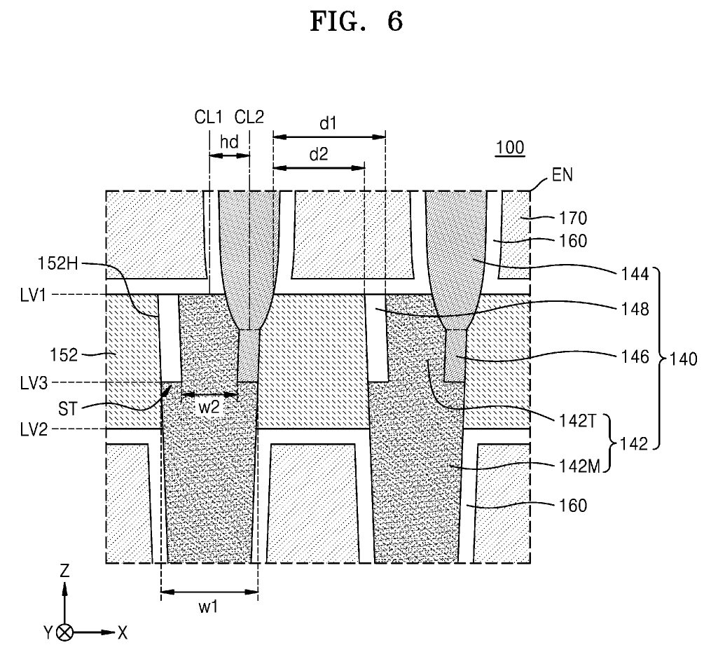

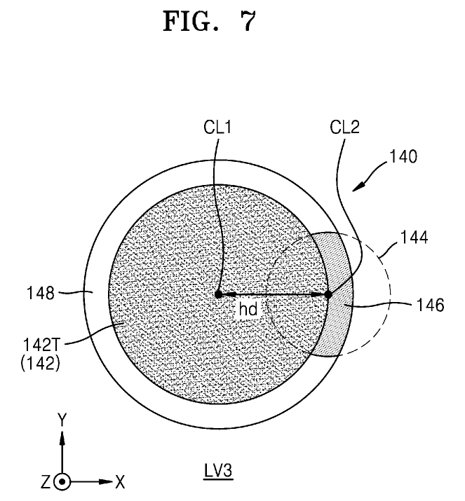

FIG. 3 is a plan view illustrating a partial configuration of the semiconductor device 100 according to some implementations. FIG. 4 is a cross-sectional view taken along a line A-A' of FIG. 3. FIG. 5 is a cross-sectional view taken along a line B-B' of FIG. 3. FIG. 6 is an enlarged view of a portion EN of FIG. 4. FIG. 7 is a planar layout diagram of a lower electrode 140 at a first vertical level LV1 of FIG. 4. For example, the plan view of FIG. 3 may represent a plan layout at a second vertical level LV2 of FIG. 4, and FIGS. 3 to 7 may illustrate components corresponding to some of the semiconductor device 100 shown in FIG. 2.

Referring to FIGS. 3 to 7, the substrate 110 may include the active area AC (see FIG. 2) defined by a device isolation film. In some implementations, the substrate 110 may include a semiconductor material such as Si, Ge, SiGe, SiC, GaAs, InAs, or InP. In some implementations, the substrate 110 may include a conductive area, for example, a well doped with impurities or a structure doped with impurities.

Although not shown, a plurality of gate line trenches extending in the first direction (the X direction) may be formed in the substrate 110, and the plurality of word lines WL (see FIG. 2) may be respectively arranged in the plurality of gate line trenches. The plurality of word lines WL may include a gate insulating layer and a gate electrode.

A lower structure 120 may be arranged on a top surface of the substrate 110. For example, the plurality of bit lines BL, the buried contact BC, and the direct contact DC, which have been described with reference to FIG. 2, may be included in the lower structure 120.

A landing pad 130 may be arranged on the lower structure 120. The landing pad 130 may correspond to the landing pad LP described with reference to FIG. 2, and a plurality of landing pads 130 may be spaced apart by a certain distance from each other in the first direction (the X direction) and the second direction (the Y direction). A side wall of the landing pad 130 may be surrounded by a node isolation insulating layer 132 and may be electrically connected to the active area AC via the direct contact DC. The landing pad 130 may include at least one of a metal, such as ruthenium (Ru), titanium (Ti), tantalum (Ta), niobium (Nb), iridium (Ir), molybdenum (Mo), or tungsten (W), and a conductive metal nitride, such as titanium nitride (TiN), tantalum nitride (TaN), niobium nitride (NbN), molybdenum nitride (MoN), or tungsten nitride (WN). In some implementations, the landing pad 130 may include titanium nitride (TiN).

An etch stop layer 134 may be formed on the landing pad 130 and the node isolation insulating layer 132. The etch stop layer 134 may include an opening 134H exposing a top surface of the landing pad 130. In some implementations, the etch stop layer 134 may include silicon nitride, silicon oxynitride, or silicon carbon nitride (SiCN).

A capacitor structure CS may be arranged on the etch stop layer 134. The capacitor structure CS may include a plurality of lower electrodes 140 electrically connected to the landing pad 130, a capacitor dielectric layer 160 conformally covering the plurality of lower electrodes 140, and an upper electrode 170 on the capacitor dielectric layer 160.

The plurality of lower electrodes 140 may be respectively arranged on the plurality of landing pads 130, and a bottom portion of the lower electrode 140 may be arranged in the opening 134H in the etch stop layer 134. The width of the bottom portion of the lower electrode 140 may be less than the width of the landing pad 130, and accordingly, the entire bottom surface of the lower electrode 140 may be in contact with the landing pad 130.

In some implementations, the lower electrode 140 may include a first electrode layer 142 arranged on the landing pad 130 and a second electrode layer 144 arranged on the first electrode layer 142. The first electrode layer 142 and the second electrode layer 144 may extend to a relatively large height in a vertical direction (Z) perpendicular to the top surface of the substrate 110. The lower electrode 140 may further include a conductive skin layer 146 and an insulating skin layer 148, which are arranged on a side wall of the first electrode layer 142.

In some implementations, the first electrode layer 142 may include a first main electrode portion 142M and a first electrode top portion 142T. The first main electrode portion 142M may extend in the vertical direction (Z), and the first electrode top portion 142T may be arranged on a top surface of the first main electrode portion 142M. In some implementations, the first electrode top portion 142T may be integrally connected to the first main electrode portion 142M. In some implementations, the top surface of the first main electrode portion 142M may have a first width w1 in a first horizontal direction (X), and a bottom surface of the first electrode top portion 142T may have a second width w2 that is less than the first width w1 in the first horizontal direction (X).

In some implementations, the bottom surface of the first electrode top portion 142T has a smaller width than the top surface of the first main electrode portion 142M, and a step ST may be defined at a boundary between a side wall of the first electrode top portion 142T and an edge of the top surface of the first main electrode portion 142M. In some implementations, a side wall of the first main electrode portion 142M may protrude outwardly relative to the side wall of the first electrode top portion 142T.

In some implementations, the first electrode top portion 142T and the first main electrode portion 142M may be in a concentric relationship. For example, a first center line CL1 (see FIG. 6) may be an imaginary line in the vertical direction (Z), which passes through a central point of a top surface of the first electrode top portion 142T, and the first center line CL1 may be an imaginary line in the vertical direction (Z), which passes through a central point of the top surface of the first main electrode portion 142M.

In some implementations, the second electrode layer 144 may extend in the vertical direction (Z), on the first electrode layer 142, and the second electrode layer 144 may be offset in the first horizontal direction (X) from the first electrode layer 142. In this regard, when the second electrode layer 144 is offset in the first horizontal direction (X) from the first electrode layer 142, it may mean that a center of a bottom portion of the second electrode layer 144 is spaced apart from a center of the first electrode layer 142 in a lateral direction (e.g., in a horizontal direction).

For example, as shown in FIGS. 6 and 7, a second center line CL2, which is an imaginary line in the vertical direction (Z) passing through a central point of the bottom portion of the second electrode layer 144, may be spaced apart, by a separation distance hd in the first horizontal direction (X), from the first center line CL1 passing through the top surface of the first electrode top portion 142T or the central point of the top surface of the first main electrode portion 142M.

FIGS. 6 and 7 illustrate an example in which the second center line CL2 is spaced apart by the separation distance hd from the first center line CL1 in the first horizontal direction (X). However, the present disclosure is not limited to the first horizontal direction (X), and the second center line CL2 may be spaced apart from the first center line CL1 in a second horizontal direction (Y), or in a diagonal direction between the first horizontal direction (X) and the second horizontal direction (Y).

In some implementations, the bottom portion of the second electrode layer 144 may be arranged at a lower vertical level than a top surface of the first electrode layer 142 (for example, the top surface of the first electrode top portion 142T), and accordingly, the area of contact between the first electrode top portion 142T and the second electrode layer 144 may be relatively large.

In some implementations, the conductive skin layer 146 and the insulating skin layer 148 may be arranged on the side wall of the first electrode top portion 142T of the first electrode layer 142.

In some implementations, the conductive skin layer 146 may be arranged on a first portion of the side wall of the first electrode top portion 142T and may be in contact with a bottom surface of the second electrode layer 144. In some implementations, the conductive skin layer 146 may be integrally formed with the bottom surface of the second electrode layer 144, and accordingly, a boundary between the conductive skin layer 146 and the second electrode layer 144 may not be identifiable. In some implementations, the conductive skin layer 146 may overlap the second electrode layer 144 in the vertical direction (Z). In some implementations, a top surface of the conductive skin layer 146 and the bottom surface of the second electrode layer 144 may be integrally connected to each other.

In some implementations, the insulating skin layer 148 may be arranged on a second portion of the side wall of the first electrode top portion 142T and may be in contact with the top surface of the first main electrode portion 142M. The insulating skin layer 148 may be arranged at a position that does not vertically overlap the second electrode layer 144.

In some implementations, as shown in FIG. 7, in a plan view, the conductive skin layer 146 may surround a first portion of an outer periphery of the first electrode top portion 142T, and the insulating skin layer 148 may surround a second portion of the outer periphery of the first electrode top portion 142T. The outer periphery of the first electrode top portion 142T may be surrounded by the conductive skin layer 146 and the insulating skin layer 148.

In some implementations, a bottom surface of the insulating skin layer 148 may be arranged at the same level as a bottom surface of the conductive skin layer 146. The bottom surface of the insulating skin layer 148 and the bottom surface of the conductive skin layer 146 may be in contact with the edge of the top surface of the first main electrode portion 142M. In some implementations, the thickness of the insulating skin layer 148 may be substantially equal or similar to the thickness of the conductive skin layer 146.

In a manufacturing process according to some implementations, after the first main electrode portion 142M is formed, an etch-back process is performed on a portion of an upper side of the first main electrode portion 142M to reduce a certain thickness of the side wall of the first main electrode portion 142M, such that the first electrode top portion 142T may be formed and the insulating skin layer 148 may be formed on the side wall of the first electrode top portion 142T. Afterwards, in an opening etching process for forming the second electrode layer 144, an extended space may be formed by removing a portion of the insulating skin layer 148, and the conductive skin layer 146 may be filled in the extended space.

In some implementations, a first portion of the side wall of the first main electrode portion 142M (for example, a right side wall of the first main electrode portion 142M shown in FIG. 7) may be aligned with a side wall of the conductive skin layer 146. In this regard, when one side wall is aligned with another side wall, it may mean that the one side wall and the other side wall are continuously and/or smoothly connected to each other. In some implementations, the first portion of the side wall of the first main electrode portion 142M may have substantially the same slope as the side wall of the conductive skin layer 146 and may be continuously and/or smoothly connected to the side wall of the conductive skin layer 146. In some implementations, the first portion of the side wall of the first main electrode portion 142M may vertically extend, the side wall of the conductive skin layer 146 may vertically extend, and the first portion of the side wall of the first main electrode portion 142M and the side wall of the conductive skin layer 146 may be continuously and/or smoothly connected to each other.

In some implementations, a second portion of the side wall of the first main electrode portion 142M (for example, a left side wall of the first main electrode portion 142M shown in FIG. 7) may be aligned with a side wall of the insulating skin layer 148. In some implementations, the second portion of the side wall of the first main electrode portion 142M may have substantially the same slope as the side wall of the insulating skin layer 148 and may be continuously and/or smoothly connected to the side wall of the insulating skin layer 148. In some implementations, the second portion of the side wall of the first main electrode portion 142M may vertically extend, the side wall of the insulating skin layer 148 may vertically extend, and the second portion of the side wall of the first main electrode portion 142M and the side wall of the insulating skin layer 148 may be continuously and/or smoothly connected to each other.

In some implementations, the first electrode layer 142, the second electrode layer 144, and the conductive skin layer 146 may include at least one selected from a metal, such as ruthenium (Ru), titanium (Ti), tantalum (Ta), niobium (Nb), iridium (Ir), molybdenum (Mo), or tungsten (W), a conductive metal nitride, such as titanium nitride (TiN), tantalum nitride (TaN), niobium nitride (NbN), molybdenum nitride (MoN), or tungsten nitride (WN), and a conductive metal oxide, such as iridium oxide (IrO₂), ruthenium oxide (RuO₂), or strontium ruthenium oxide (SrRuO₃). In some implementations, the insulating skin layer 148 may include at least one of silicon oxide, silicon oxynitride, silicon carbon nitride, silicon boron nitride, and a low-k dielectric material.

In some implementations, a first supporter pattern 152 and a second supporter pattern 154 may be spaced apart from each other in the vertical direction (Z), on a side wall of the lower electrode 140.

In some implementations, the first supporter pattern 152 may be arranged on the side wall of the conductive skin layer 146, the side wall of the insulating skin layer 148, and an upper side wall of the first main electrode portion 142M. In some implementations, the first supporter pattern 152 may include a first opening 152H, and the first electrode top portion 142T, the conductive skin layer 146, and the insulating skin layer 148 may be arranged in the first opening 152H. In addition, the bottom portion of the second electrode layer 144 may be further arranged in the first opening 152H.

In some implementations, a top surface of the first supporter pattern 152 may be arranged at the same vertical level (for example, the first vertical level LV1 of FIG. 4) as the top surface of the first electrode top portion 142T and a top surface of the insulating skin layer 148. In some implementations, a bottom surface of the first supporter pattern 152 may be arranged at the second vertical level LV2 that is lower than a third vertical level LV3 of the bottom surface of the conductive skin layer 146 and the bottom surface of the insulating skin layer 148. In some implementations, unlike as shown in FIG. 7, the bottom surface of the first supporter pattern 152 may be arranged at the same vertical level as the bottom surface of the conductive skin layer 146 and the bottom surface of the insulating skin layer 148.

In some implementations, the second supporter pattern 154 may be arranged on an upper side wall of the second electrode layer 144. The second supporter pattern 154 may have a top surface arranged at the same vertical level as a top surface of the second electrode layer 144. The second supporter pattern 154 may include a second opening 154H, and the second electrode layer 144 may be arranged in the second opening 154H.

In some implementations, the first supporter pattern 152 and the second supporter pattern 154 may include silicon nitride, silicon oxynitride, silicon boron nitride (SiBN), or silicon carbon nitride (SiCN).

In some implementations, in addition to the first supporter pattern 152 and the second supporter pattern 154, additional supporter patterns may be arranged on the side wall of the lower electrode 140, and for example, may be spaced apart from the first supporter pattern 152 and the second supporter pattern 154 in the vertical direction (Z).

In some implementations, as schematically shown in FIG. 3, the first opening 152H in the first supporter pattern 152 may have a shape extending in one direction such that four first electrode layers 142 pass through the first opening 152H. Although not shown, the second opening 154H in the second supporter pattern 154 may have a shape extending in one direction such that four second electrode layers 144 pass through the second opening 154H. However, the shape of the first opening 152H and the shape of the second opening 154H are not limited thereto. For example, more than four first electrode layers 142 may be arranged in the first opening 152H, and the planar shape of the first opening 152H may vary. In addition, more than four second electrode layers 144 may be arranged in the second opening 154H, and the planar shape of the second opening 154H may vary.

In some implementations, the capacitor dielectric layer 160 may be arranged on the side wall and a top surface of the lower electrode 140. The capacitor dielectric layer 160 may extend from the side wall of the lower electrode 140 onto the top surfaces and bottom surfaces of the first supporter pattern 152 and the second supporter pattern 154, and may be arranged on the etch stop layer 134. The capacitor dielectric layer 160 may have a thickness of about 20 Å to about 100 Å in a direction perpendicular to the top surface of the lower electrode 140, but is not limited thereto.

In some implementations, as shown in FIG. 5, a portion of the capacitor dielectric layer 160 arranged in the first opening 152H may be arranged to cover the step ST of the first electrode layer 142, and the portion of the capacitor dielectric layer 160 arranged in the first opening 152H may be conformally arranged on the side wall of the conductive skin layer 146.

In some implementations, the capacitor dielectric layer 160 may include at least one of zirconium oxide, hafnium oxide, titanium oxide, niobium oxide, tantalum oxide, yttrium oxide, strontium titanium oxide, barium strontium titanium oxide, scandium oxide, and lanthanide oxide.

The upper electrode 170 covering the lower electrode 140 may be arranged on the capacitor dielectric layer 160. The upper electrode 170 may include at least one selected from a metal, such as ruthenium (Ru), titanium (Ti), tantalum (Ta), niobium (Nb), iridium (Ir), molybdenum (Mo), or tungsten (W), a conductive metal nitride, such as titanium nitride (TiN), tantalum nitride (TaN), niobium nitride (NbN), molybdenum nitride (MoN), or tungsten nitride (WN), and a conductive metal oxide, such as iridium oxide (IrO₂), ruthenium oxide (RuO₂), or strontium ruthenium oxide (SrRuO₃).

Optionally, an interfacial layer may be further formed between the capacitor dielectric layer 160 and the upper electrode 170. The interfacial layer may include at least one of a metal oxide, such as titanium oxide, tantalum oxide, niobium oxide, molybdenum oxide, or iridium oxide, and a metal oxynitride, such as titanium oxynitride (TiON), tantalum oxynitride (TaON), niobium oxynitride (NbON), or molybdenum oxynitride (MoON).

In general, a lower electrode having a two-layer structure including a first electrode layer and a second electrode layer may increase the height of the lower electrode. However, when misalignment occurs in a process of patterning the second electrode layer, there may be a problem in which the second electrode layer is connected to or arranged adjacent to the adjacent first electrode layer, resulting in a bridge defect. For example, a separation distance between one second electrode layer and an adjacent first electrode layer may correspond to a second distance d2 in FIG. 6. One way to address this issue is to reduce the width of an upper side of a first electrode layer by performing a trimming process on a side wall of the upper side of the first electrode layer. However, when misalignment occurs in a process of forming a second electrode layer on a reduced top surface of the first electrode layer, there may be a problem in which a sufficiently large area of contact between the first electrode layer and the second electrode layer is not secured.

However, according to some implementations of the present disclosure, after performing the trimming process on the side wall of the upper side of the first electrode layer, the insulating skin layer 148 is formed on the side wall of the upper side of the first electrode layer, then an opening for forming the second electrode layer 144 is formed, and the insulating skin layer 148 exposed through the opening is removed to form an extended space. Afterwards, in a process of embedding the second electrode layer 144, the conductive skin layer 146 integrally connected to the second electrode layer 144 may be formed in the extended space.

After performing such a trimming process, a separation distance between one second electrode layer 144 and the adjacent first electrode layer 142 may correspond to a first distance d1 in FIG. 6, which may be greater than the second distance d2 corresponding to a separation distance between one second electrode layer 144 and the adjacent first electrode layer 142 if the trimming process had not been performed. Therefore, the risk of bridge defects in a process of forming the lower electrode 140 may be reduced and/or prevented. In addition, because the conductive skin layer 146 is formed between the second electrode layer 144 and the side wall of the first electrode layer 142, a sufficiently large area of contact may be secured between the first electrode layer 142, the second electrode layer 144, and the conductive skin layer 146. Therefore, the semiconductor device 100 may have excellent electrical characteristics.

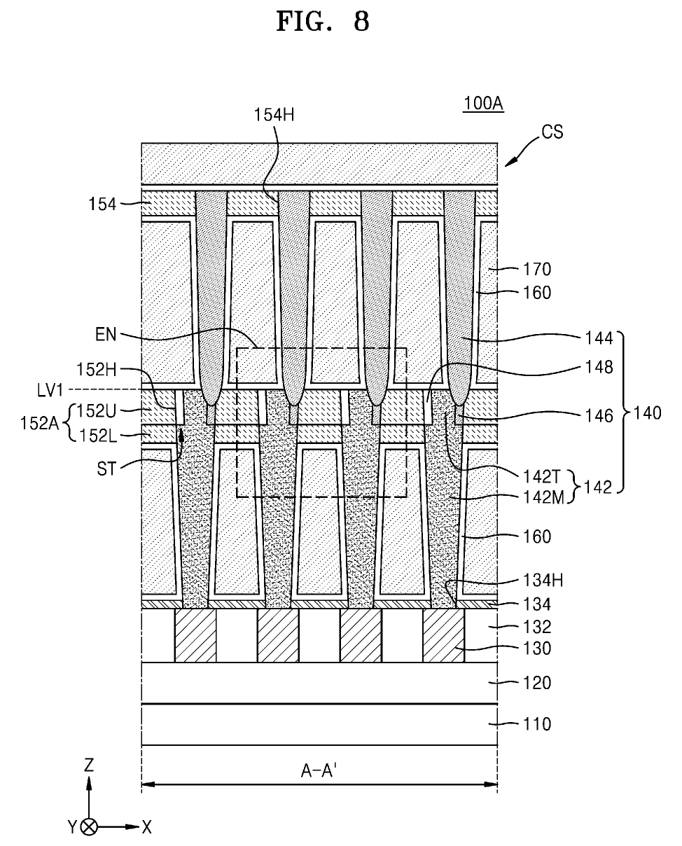

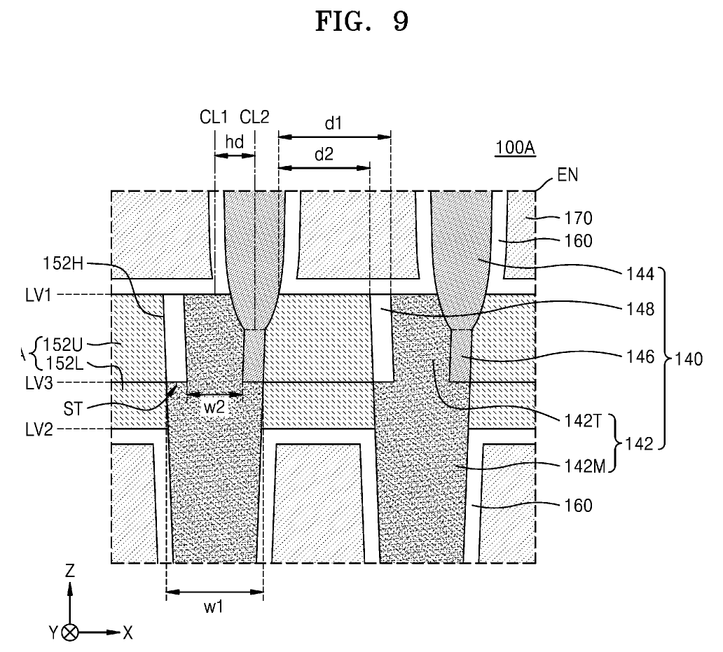

FIG. 8 is a cross-sectional view illustrating a semiconductor device 100A according to some implementations. FIG. 9 is an enlarged view of a portion EN of FIG. 8.

Referring to FIGS. 8 and 9, a first supporter pattern 152A may have a double-layer structure. The first supporter pattern 152A may include a lower supporter pattern 152L and an upper supporter pattern 152U. In some implementations, a bottom surface of the upper supporter pattern 152U may be coplanar with the bottom surface of the conductive skin layer 146 and the bottom surface of the insulating skin layer 148. In some implementations, a top surface of the lower supporter pattern 152L may be coplanar with (for example, may be arranged at the same vertical level as) the edge of the top surface of the first main electrode portion 142M.

In some implementations, the lower supporter pattern 152L may function as an etch stop layer and/or a protective film in an etching process for forming the first electrode top portion 142T by etching back an upper side of a first electrode material layer 142L. In some implementations, the upper supporter pattern 152U may be formed on the lower supporter pattern 152L to surround the side wall of the insulating skin layer 148 after the insulating skin layer 148 is formed on the side wall of the first electrode top portion 142T.

In some implementations, the lower supporter pattern 152L and the upper supporter pattern 152U may include silicon nitride, silicon oxynitride, silicon boron nitride (SiBN), or silicon carbon nitride (SiCN). In some implementations, the lower supporter pattern 152L and the upper supporter pattern 152U may include the same material. In some implementations, the lower supporter pattern 152L and the upper supporter pattern 152U may include different materials from each other.

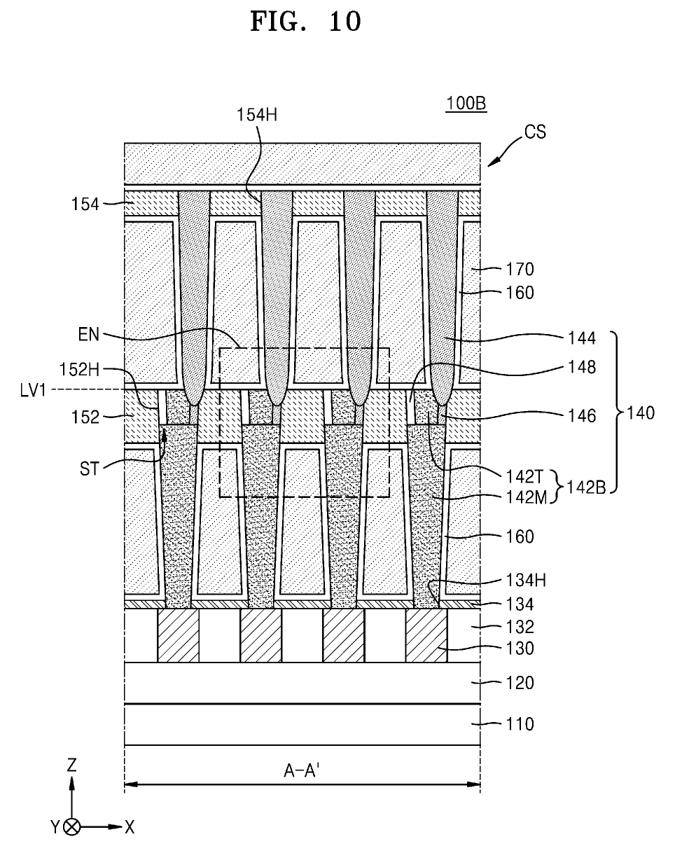

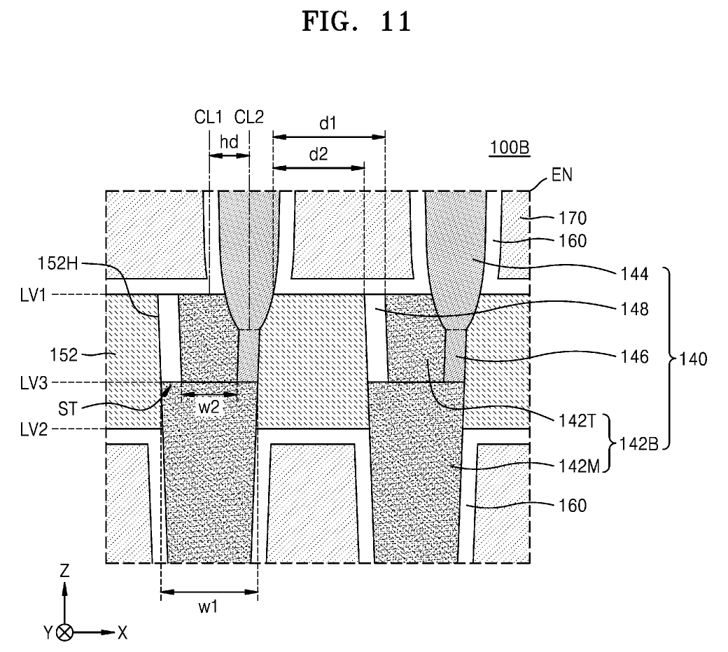

FIG. 10 is a cross-sectional view illustrating a semiconductor device 100B according to some implementations. FIG. 11 is an enlarged view of a portion EN of FIG. 10.

Referring to FIGS. 10 and 11, a first electrode layer 142B may include the first main electrode portion 142M and the first electrode top portion 142T, and the bottom surface of the first electrode top portion 142T may be arranged on the top surface of the first main electrode portion 142M. In some implementations, the first main electrode portion 142M may not be integrally formed with the first electrode top portion 142T.

In some implementations, after the first main electrode portion 142M is formed first, the insulating skin layer 148 may be formed on the top surface of the first main electrode portion 142M and on a side wall of the first opening 152H in the first supporter pattern 152, and then, the first electrode top portion 142T may be formed on the top surface of the first main electrode portion 142M and in the first opening 152H in the first supporter pattern 152.

In some implementations, the bottom surface of the first electrode top portion 142T may be coplanar with the bottom surface of the conductive skin layer 146 and the bottom surface of the insulating skin layer 148, and the bottom surface of the first electrode top portion 142T, the bottom surface of the conductive skin layer 146, and the bottom surface of the insulating skin layer 148 may be in contact with the top surface of the first main electrode portion 142M.

In some implementations, the first main electrode portion 142M and the first electrode top portion 142T may include at least one selected from a metal, such as ruthenium (Ru), titanium (Ti), tantalum (Ta), niobium (Nb), iridium (Ir), molybdenum (Mo), or tungsten (W), a conductive metal nitride, such as titanium nitride (TiN), tantalum nitride (TaN), niobium nitride (NbN), molybdenum nitride (MoN), or tungsten nitride (WN), and a conductive metal oxide, such as iridium oxide (IrO₂), ruthenium oxide (RuO₂), or strontium ruthenium oxide (SrRuO₃).

In some implementations, the first main electrode portion 142M and the first electrode top portion 142T may include the same material. In some implementations, the first main electrode portion 142M and the first electrode top portion 142T may include different materials from each other.

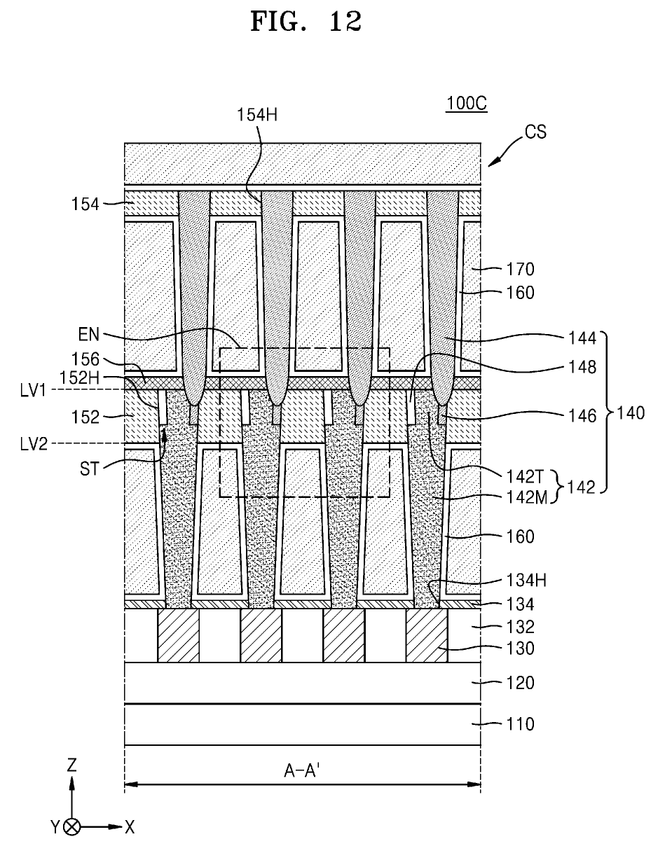

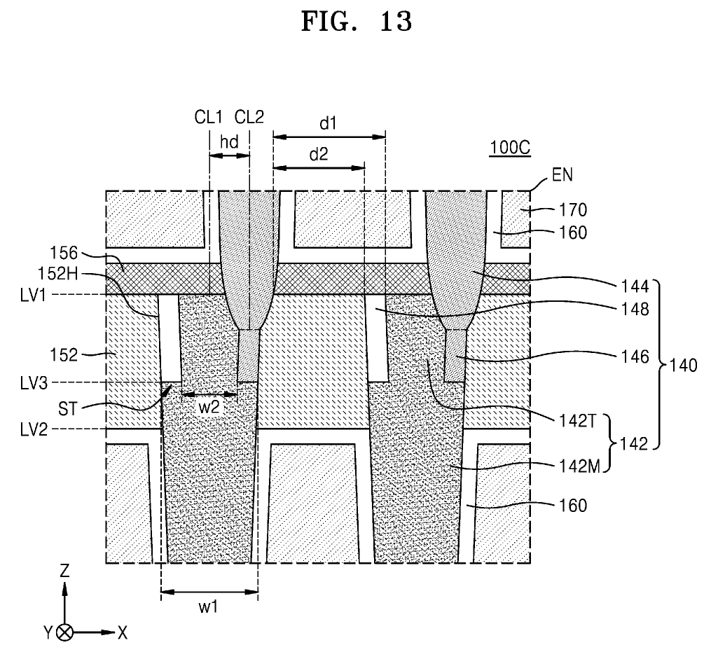

FIG. 12 is a cross-sectional view illustrating a semiconductor device 100C according to some implementations. FIG. 13 is an enlarged view of a portion EN of FIG. 12.

Referring to FIGS. 12 and 13, a stopper layer 156 may be further arranged on the top surface of the first supporter pattern 152, the top surface of the first electrode top portion 142T, and the top surface of the insulating skin layer 148. The bottom portion of the second electrode layer 144 may pass through the stopper layer 156 and extend to a vertical level lower than a bottom surface of the stopper layer 156. In some implementations, the stopper layer 156 may include silicon nitride, silicon oxynitride, silicon boron nitride (SiBN), or silicon carbon nitride (SiCN).

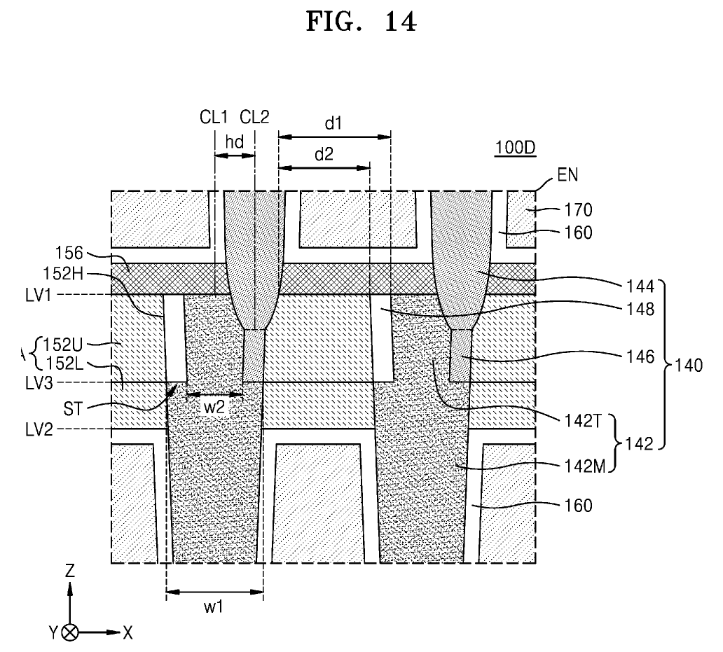

FIG. 14 is a cross-sectional view illustrating a semiconductor device 100D according to some implementations.

Referring to FIG. 14, the first supporter pattern 152A may include the lower supporter pattern 152L and the upper supporter pattern 152U, and the stopper layer 156 may be further arranged on a top surface of the upper supporter pattern 152U, the top surface of the first electrode top portion 142T, and the top surface of the insulating skin layer 148. The semiconductor device 100D described with reference to FIG. 14 may have similar technical characteristics to the semiconductor device 100A described with reference to FIGS. 8 and 9, except that the stopper layer 156 is further formed.

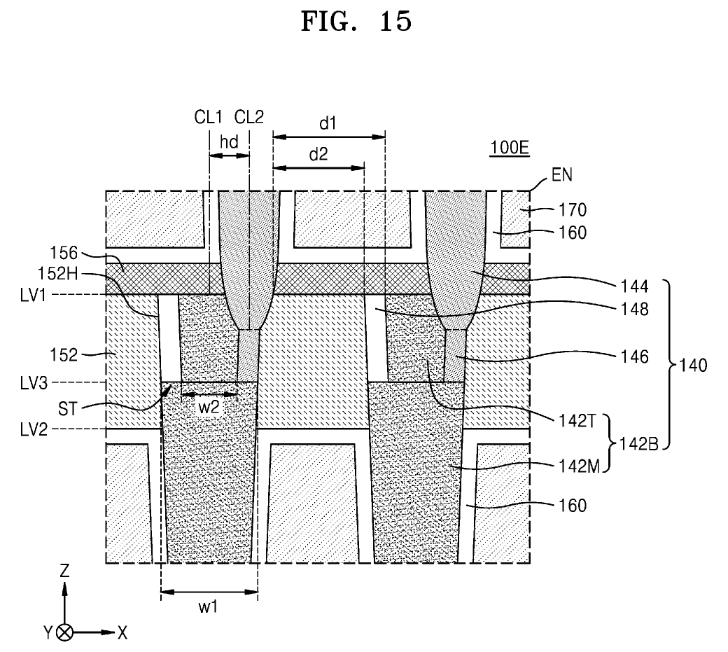

FIG. 15 is a cross-sectional view illustrating a semiconductor device 100E according to some implementations.

Referring to FIG. 15, a first electrode layer 142B may include the first main electrode portion 142M and the first electrode top portion 142T, and the bottom surface of the first electrode top portion 142T may be arranged on the top surface of the first main electrode portion 142M. The stopper layer 156 may be further arranged on the top surface of the first supporter pattern 152, the top surface of the first electrode top portion 142T, and the top surface of the insulating skin layer 148. The semiconductor device 100E described with reference to FIG. 15 may have similar technical characteristics to the semiconductor device 100B described with reference to FIGS. 10 and 11, except that the stopper layer 156 is further formed.

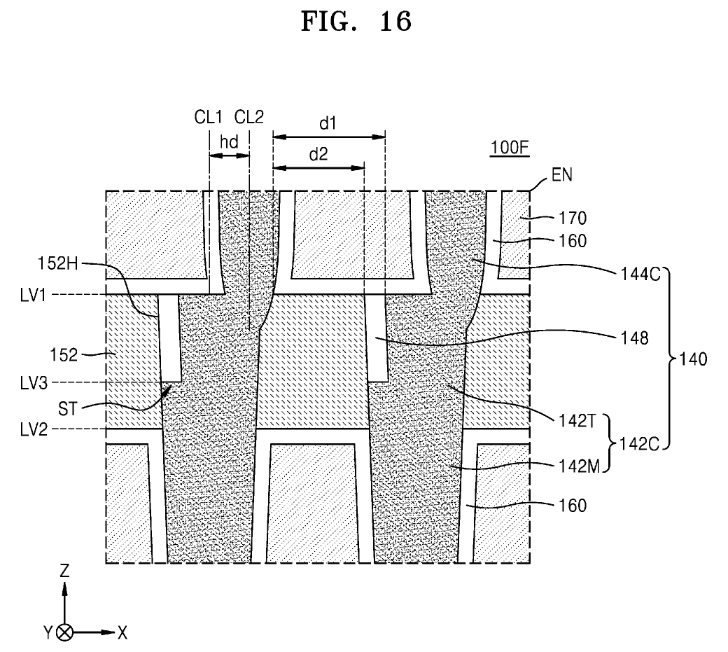

FIG. 16 is a cross-sectional view illustrating a semiconductor device 100F according to some implementations.

Referring to FIG. 16, the lower electrode 140 may include a first electrode layer portion 142C, a second electrode layer portion 144C, and the insulating skin layer 148. A top surface of the first electrode layer portion 142C may be coplanar with a top surface of a first supporter layer 152M. The second electrode layer portion 144C may be arranged at a higher vertical level than the first electrode layer portion 142C, and the second electrode layer portion 144C may be integrally connected to the first electrode layer portion 142C. In this regard, when the second electrode layer portion 144C is integrally connected to the first electrode layer portion 142C, it may mean that a boundary between the second electrode layer portion 144C and the first electrode layer portion 142C is not clearly identified.

In some implementations, the first electrode layer portion 142C may include the first main electrode portion 142M and the first electrode top portion 142T, and the step ST may be defined between the first electrode top portion 142T and the first main electrode portion 142M. The insulating skin layer 148 may be arranged on a portion of the side wall of the first electrode top portion 142T. The insulating skin layer 148 may be arranged in the step ST. The insulating skin layer 148 includes a first side wall and a second side wall opposite to the first side wall, wherein the first side wall of the insulating skin layer 148 may be in contact with the side wall of the first electrode top portion 142T, and the second side wall of the insulating skin layer 148 may be aligned with or continuously connected to the side wall of the first main electrode portion 142M.

In some implementations, the first electrode layer portion 142C may have an asymmetrical shape with respect to the first center line CL1 passing through the central point of the top surface of the first main electrode portion 142M of the first electrode layer portion 142C. For example, as shown in FIG. 16, the step ST may be defined on a side wall of the first electrode layer portion 142C, which is arranged on a left side of the first center line CL1, and the step ST may not be defined on a side wall of the first electrode layer portion 142C, which is arranged on a right side of the first center line CL1. In addition, the insulating skin layer 148 may be arranged on the side wall of the first electrode layer portion 142C, which is arranged on the left side of the first center line CL1. The side wall of the first electrode layer portion 142C, which is arranged on the right side of the first center line CL1, may be in contact with the first supporter layer 152M.

In some implementations, a center line of the first electrode top portion 142T may be offset or spaced apart in the lateral direction (for example, in the first horizontal direction (X) in FIG. 16) from a center line (for example, the first center line CL1) of the first main electrode portion 142M. In addition, a center line (for example, the second center line CL2) of the second electrode layer portion 144C may be offset or spaced apart in the lateral direction (for example, in the first horizontal direction (X) in FIG. 16) from the center line (for example, the first center line CL1) of the first main electrode portion 142M.

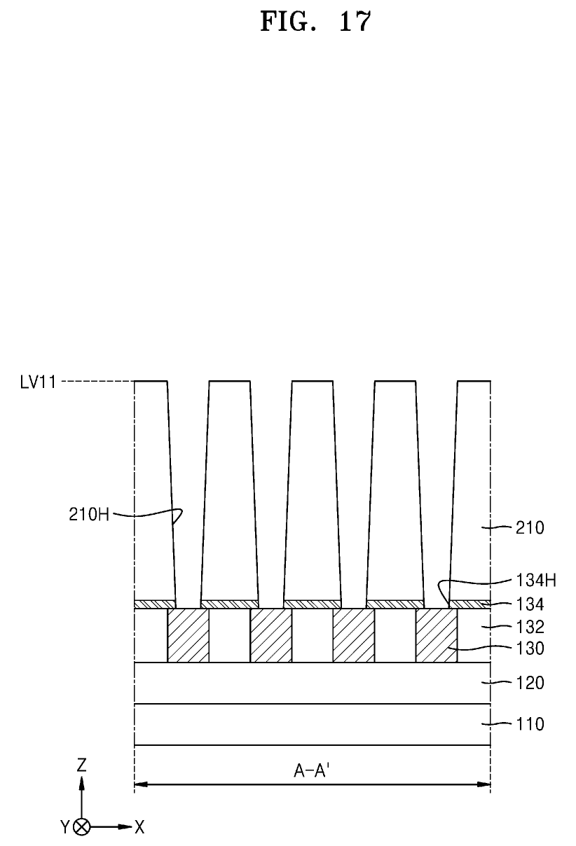

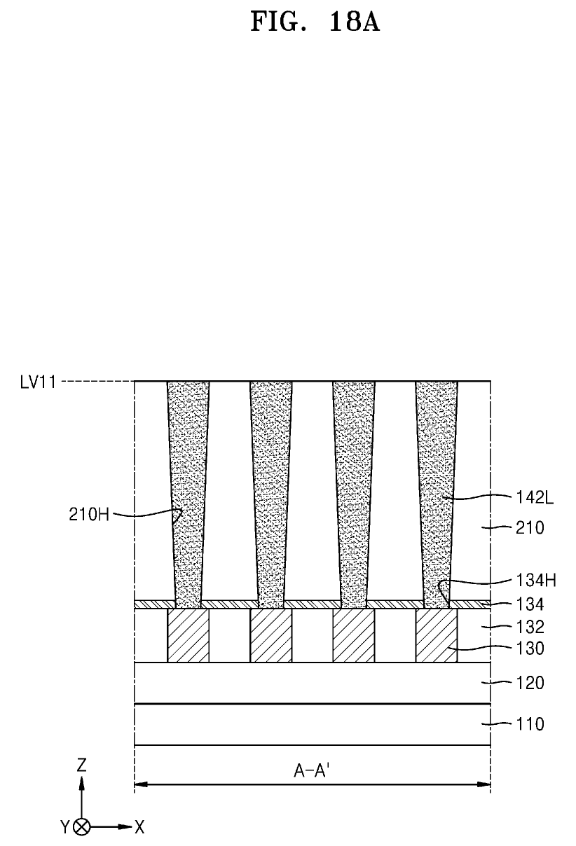

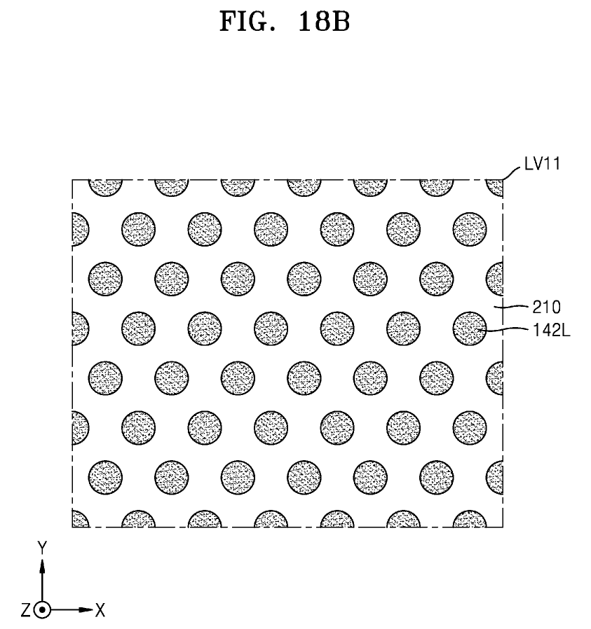

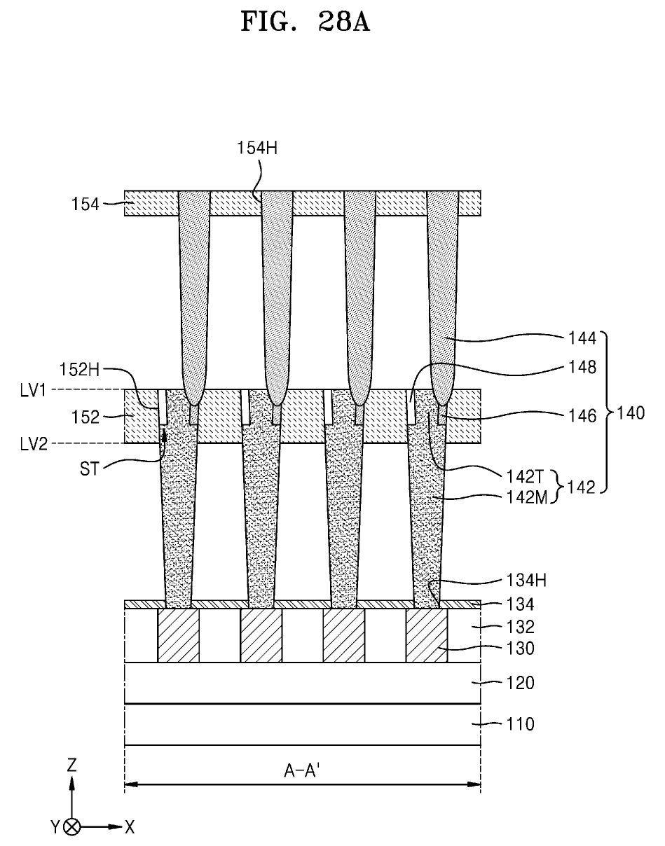

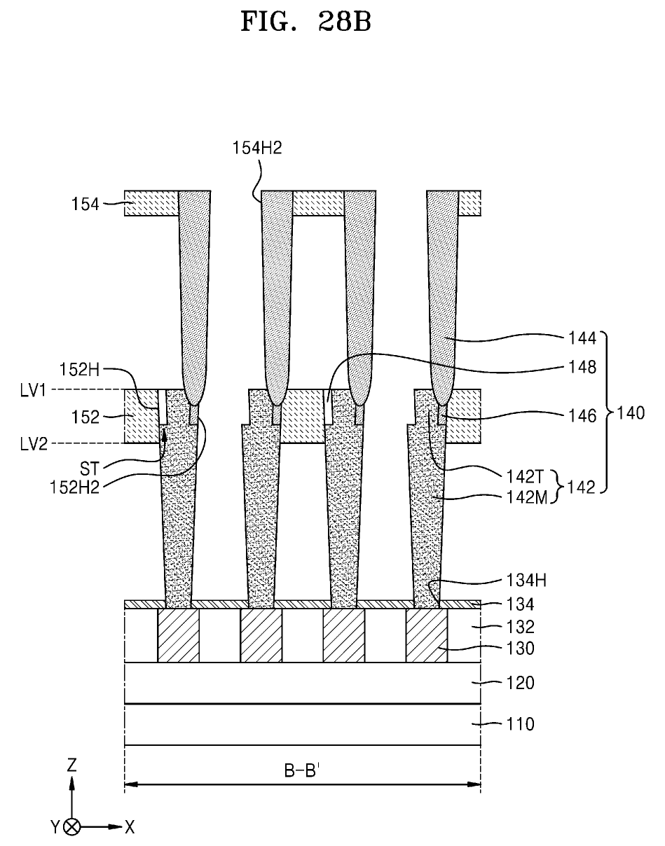

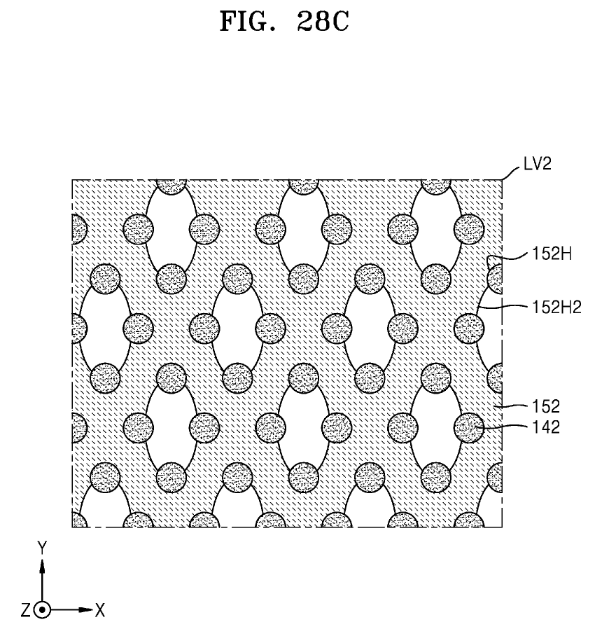

FIGS. 17, 18A, 18B, 19 to 22, 23A, 23B, 24 to 27, 28A, 28B, 28C, and 29 are schematic views illustrating a method of manufacturing the semiconductor device 100 according to a process sequence, according to some implementations. In detail, FIGS. 17, 18A, 19 to 22, 23A, 24 to 27, 28A, and 29 are cross-sectional views taken along a line A-A' of FIG. 3, FIG. 28B is a cross-sectional view taken along a line B-B' of FIG. 3, and FIGS. 18B, 23B, and 28C are plan views of FIGS. 18A, 23B, and 28A, respectively.

Referring to FIG. 17, the lower structure 120 may be formed on the top surface of the substrate 110, and the landing pad 130 and the node isolation insulating layer 132 surrounding the side wall of the landing pad 130 may be formed on the lower structure 120.

Afterwards, the etch stop layer 134 and a first mold insulating layer 210 may be sequentially formed on the landing pad 130 and the node isolation insulating layer 132.

In some implementations, the first mold insulating layer 210 and the etch stop layer 134 may include materials having etch selectivities relative to each other. For example, when the first mold insulating layer 210 includes silicon oxide, the etch stop layer 134 may include silicon nitride, silicon oxynitride, or silicon carbon nitride (SiCN).

Afterwards, a mask pattern may be formed on the first mold insulating layer 210, and a first vertical hole 210H passing through the first mold insulating layer 210 may be formed by using the mask pattern.

In some implementations, the mask pattern may be polysilicon, silicon nitride, silicon oxide, silicon oxynitride, spin-on-hardmask (SOH), amorphous carbon layer (ACL), or a combination thereof.

The first vertical hole 210H may extend in the vertical direction (Z) to pass through the first mold insulating layer 210. After forming the first vertical hole 210H, a portion of the etch stop layer 134 may be removed, and the opening 134H communicating with the first vertical hole 210H may be formed in the etch stop layer 134. The top surface of the landing pad 130 may be exposed by the first vertical hole 210H and the opening 134H.

Referring to FIGS. 18A and 18B, a conductive layer may be used to fill the first vertical hole 210H and the opening 134H, and an upper portion of the conductive layer may be removed so that a top surface of the first mold insulating layer 210 is exposed, thereby forming the first electrode material layer 142L on the landing pad 130 and the first mold insulating layer 210.

In some implementations, a process of forming the first electrode material layer 142L may be a chemical vapor deposition (CVD) process, a metal organic CVD (MOCVD) process, an atomic layer deposition (ALD) process, or a metal organic ALD (MOALD) process.

In this regard, a top surface of the first electrode material layer 142L may be coplanar with the top surface of the first mold insulating layer 210, and for example, may be arranged at a first reference vertical level LV11.

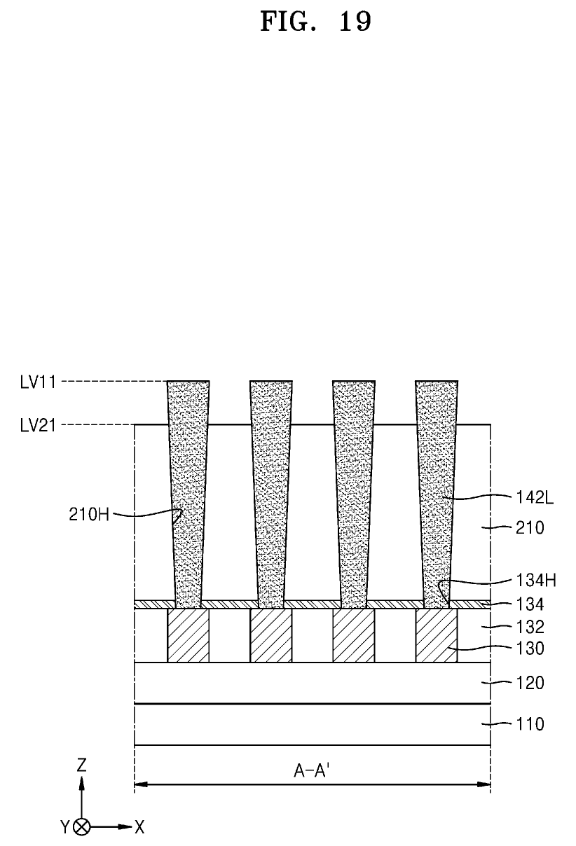

Referring to FIG. 19, the height of the first mold insulating layer 210 may be reduced by performing an etch-back process on an upper side of the first mold insulating layer 210. In some implementations, the top surface of the first mold insulating layer 210 may be arranged at the third vertical level LV3 that is lower than the first reference vertical level LV11.

In some implementations, the etch-back process for the first mold insulating layer 210 may be an etching process using etching conditions including an etch selectivity with respect to the first electrode material layer 142L. While the etch-back process for the first mold insulating layer 210 is being performed, the first electrode material layer 142L may not be removed or only a negligible amount may be removed. As a result of the etching process, the top surface of the first electrode material layer 142L may be arranged at the first reference vertical level LV11 and may protrude beyond the top surface of the first mold insulating layer 210.

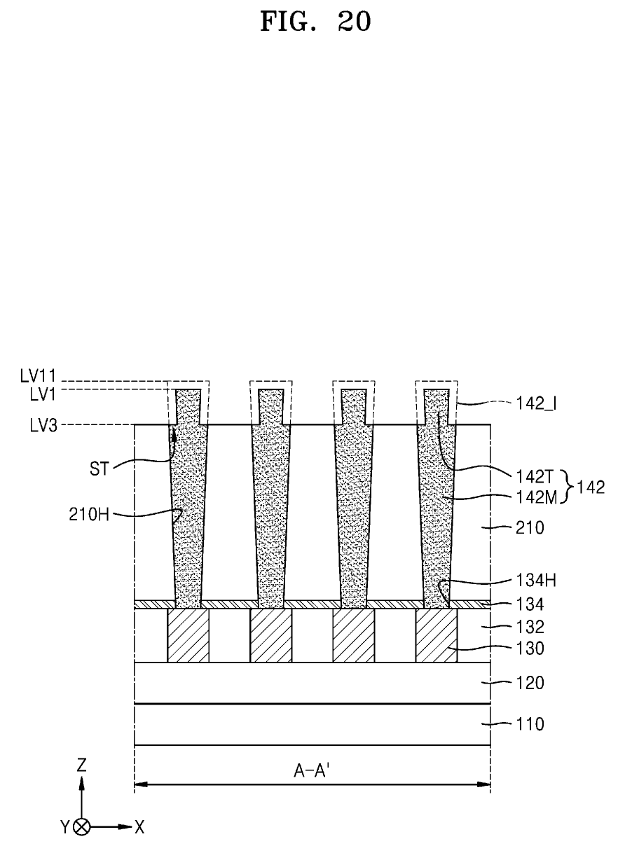

Referring to FIG. 20, a portion of the first electrode material layer 142L may be removed from a surface 142_I of the first electrode material layer 142L by performing a trimming process on the first electrode material layer 142L. In some implementations, the trimming process may include an isotropic dry etching or wet etching process. For example, when the trimming process includes wet etching, the trimming process may be performed by using an etchant including phosphoric acid, nitric acid, acetic acid, or a combination thereof.

In FIG. 20, for convenience of explanation, the surface 142_I of the first electrode material layer 142L before performing the trimming process is drawn with a dashed line. In some implementations, a portion having the same or similar thickness may be removed from the top surface and a side wall of the first electrode material layer 142L, by the trimming process, and accordingly, a first portion of the first electrode material layer 142L, arranged at a higher level than the top surface of the first mold insulating layer 210, may have a smaller width than a second portion of the first electrode material layer 142L, arranged at a lower level than or the same level as the top surface of the first mold insulating layer 210.

In this regard, the first portion of the first electrode material layer 142L, arranged at a higher level than the top surface of the first mold insulating layer 210, is referred to as the first electrode top portion 142T, and the second portion of the first electrode material layer 142L, arranged at a lower level than or the same level as the top surface of the first mold insulating layer 210, is referred to as the first main electrode portion 142M. In addition, the first electrode top portion 142T and the first main electrode portion 142M are collectively referred to as the first electrode layer 142. In some implementations, as a result of the trimming process for the first electrode material layer 142L, the step ST may be formed at a boundary between the first main electrode portion 142M and the first electrode top portion 142T. In some implementations, the top surface of the first main electrode portion 142M may have the first width w1 (see FIG. 6), and the bottom surface of the first electrode top portion 142T may have the second width w2 (see FIG. 6) that is less than the first width w1.

In some implementations, the top surface of the first main electrode portion 142M may be arranged at the third vertical level LV3 and may be coplanar with the top surface of the first mold insulating layer 210. In some implementations, because the top surface and the side wall of the first electrode top portion 142T are recessed inward from the surface 142_I of the first electrode material layer 142L (for example, the top surface and the side wall of the first electrode material layer 142L), the top surface of the first electrode top portion 142T may be arranged at first vertical level LV1 that is lower than the first reference vertical level LV11.

In some implementations, because the first main electrode portion 142M and the first electrode top portion 142T are formed by performing the trimming process on the first electrode material layer 142L, the first main electrode portion 142M and the first electrode top portion 142T may be integrally connected to each other.

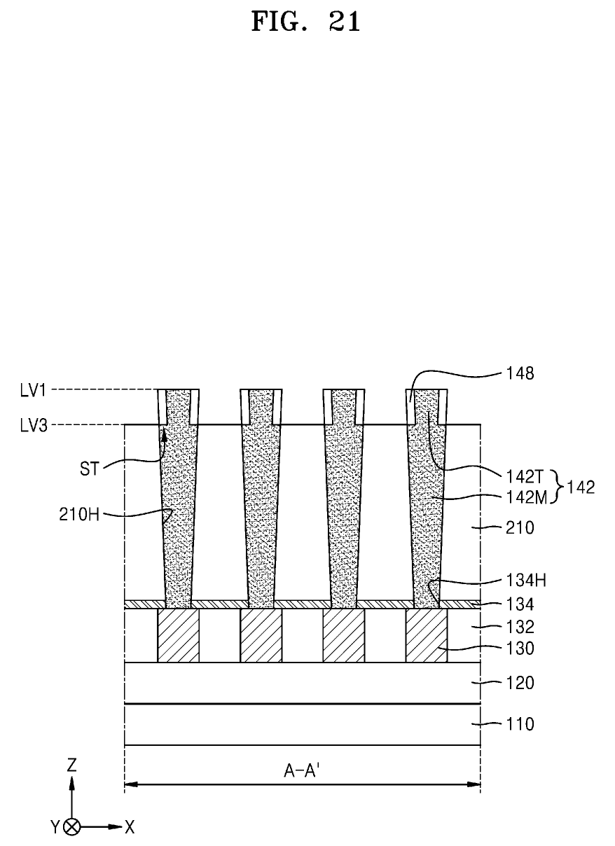

Referring to FIG. 21, an insulating layer is formed on the first electrode top portion 142T and the top surface of the first mold insulating layer 210, and the insulating skin layer 148 may remain only on the side wall of the first electrode top portion 142T by performing an anisotropic etching process on the insulating layer. In some implementations, in a plan view, the insulating skin layer 148 may have an annular or ring shape surrounding the entire side wall of the first electrode top portion 142T.

In some implementations, the insulating skin layer 148 may have a height that is the same as or similar to the height of the first electrode top portion 142T in the vertical direction (Z), wherein the top surface of the insulating skin layer 148 may be coplanar with the top surface of the first electrode top portion 142T, and the bottom surface of the insulating skin layer 148 may be coplanar with the bottom surface of the first electrode top portion 142T, the top surface of the first main electrode portion 142M, and the top surface of the first mold insulating layer 210.

In some implementations, the insulating skin layer 148 may be formed by using at least one of silicon oxide, silicon oxynitride, silicon carbon nitride, silicon boron nitride, and a low-k dielectric material.

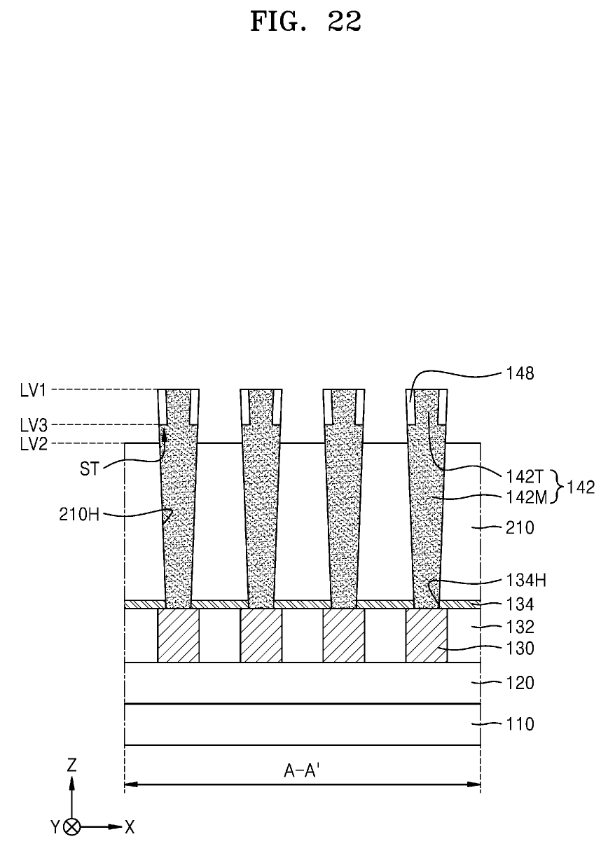

Referring to FIG. 22, the height of the first mold insulating layer 210 may be reduced by performing an etch-back process on the upper side of the first mold insulating layer 210. In some implementations, the top surface of the first mold insulating layer 210 may be arranged at the second vertical level LV2 that is lower than the third vertical level LV3.

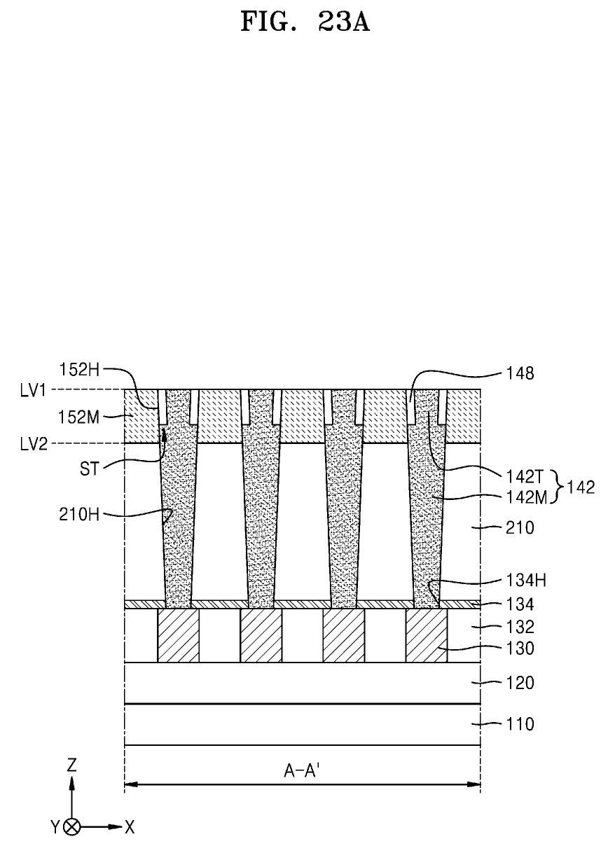

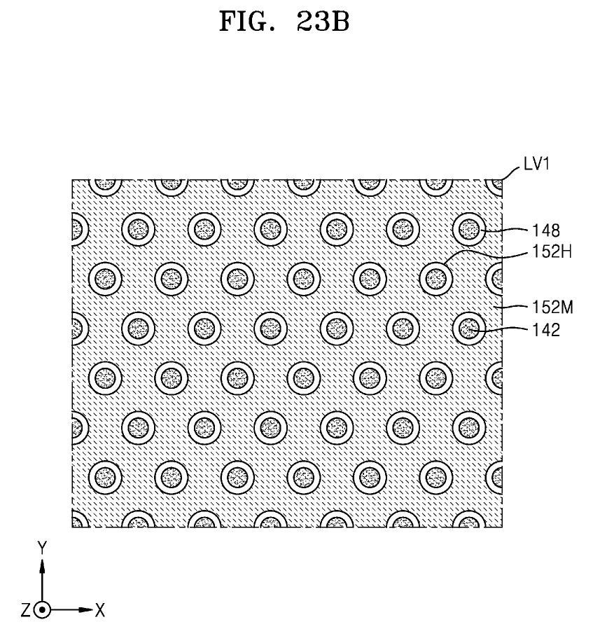

Referring to FIGS. 23A and 23B, the first supporter layer 152M may be formed on a side wall of an upper side of the first electrode layer 142 and the top surface of the first mold insulating layer 210. The first supporter layer 152M may be arranged to surround an outer side wall of the insulating skin layer 148. The insulating skin layer 148 is arranged between the first supporter layer 152M and the side wall of the first electrode top portion 142T, and thus, the first supporter layer 152M may not be in direct contact with the side wall of the first electrode top portion 142T. The first supporter layer 152M may be arranged to surround and be in direct contact with a side wall of the upper side of the first main electrode portion 142M (for example, a portion of the first main electrode portion 142M, which is arranged at a higher vertical level than the top surface of the first mold insulating layer 210). In some implementations, the first supporter layer 152M may include a plurality of first openings 152H1, and one first electrode layer 142 and one insulating skin layer 148 may be arranged in each of the plurality of first openings 152H1.

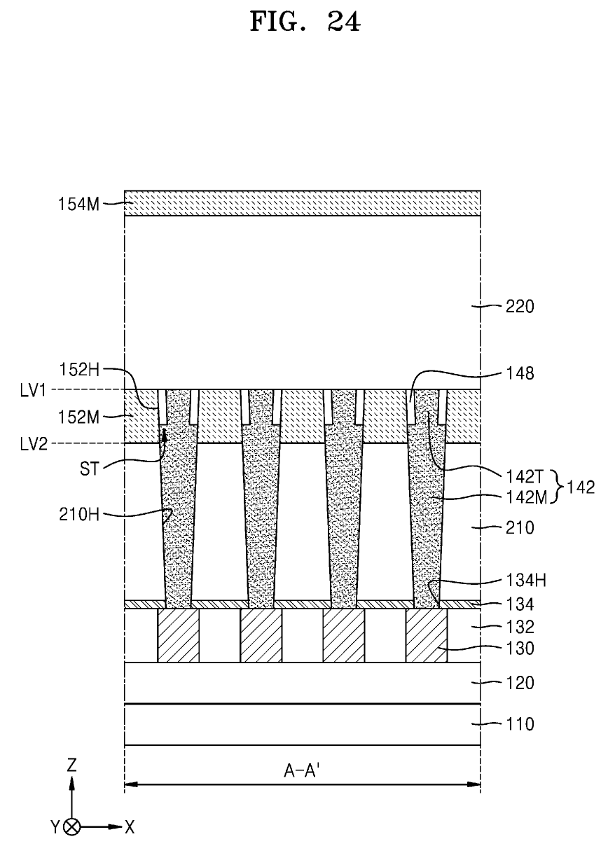

Referring to FIG. 24, a second mold insulating layer 220 and a second supporter layer 154M may be formed on the first supporter layer 152M, the first electrode layer 142, and the top surface of the insulating skin layer 148.

In some implementations, the second mold insulating layer 220 and the second supporter layer 154M may include materials having etch selectivities relative to each other. For example, when the second mold insulating layer 220 includes silicon oxide, the second supporter layer 154M may include silicon nitride, silicon oxynitride, silicon boron nitride (SiBN), or silicon carbon nitride (SiCN).

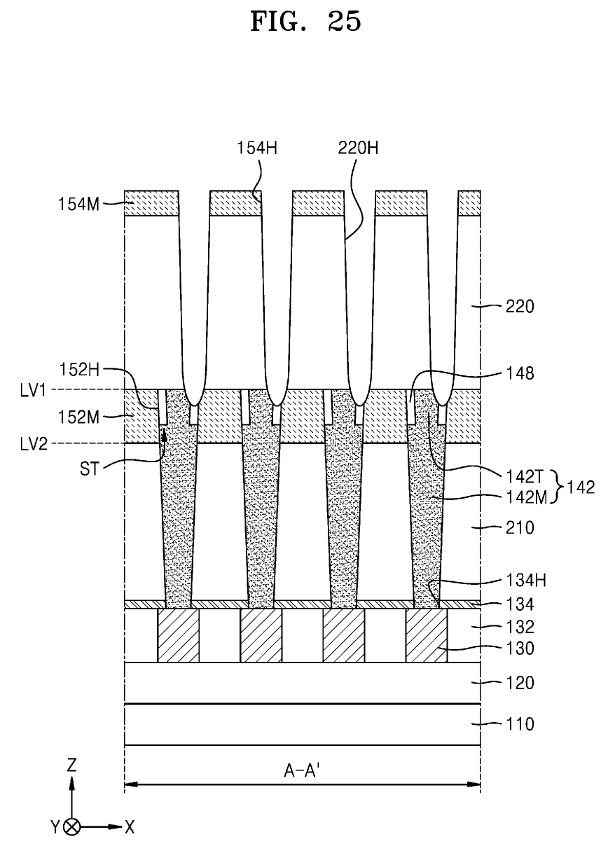

Referring to FIG. 25, a mask pattern may be formed on the second supporter layer 154M, and the second opening 154H passing through the second supporter layer 154M and a second vertical hole 220H passing through the second mold insulating layer 220 may be formed by using the mask pattern.

In some implementations, the mask pattern may be polysilicon, silicon nitride, silicon oxide, silicon oxynitride, spin-on-hardmask (SOH), amorphous carbon layer (ACL), or a combination thereof.

In some implementations, the second vertical hole 220H may extend in the vertical direction (Z) to pass through the second mold insulating layer 220. In some implementations, the second vertical hole 220H may be arranged at a position vertically overlapping the first electrode layer 142 and the insulating skin layer 148, and the top surface of the first electrode layer 142 and the top surface of the insulating skin layer 148 may be exposed at a bottom portion of the second vertical hole 220H. In some implementations, the bottom portion of the second vertical hole 220H may extend to a vertical level that is lower than the top surface of the first supporter layer 152M.

In some other implementations, the second vertical hole 220H may have a relatively flat-level bottom portion extending to a vertical level that is the same as the top surface of the first supporter layer 152M, and the top surface of the first electrode layer 142 and the top surface of the insulating skin layer 148 may be exposed at the flat bottom portion of the second vertical hole 220H.

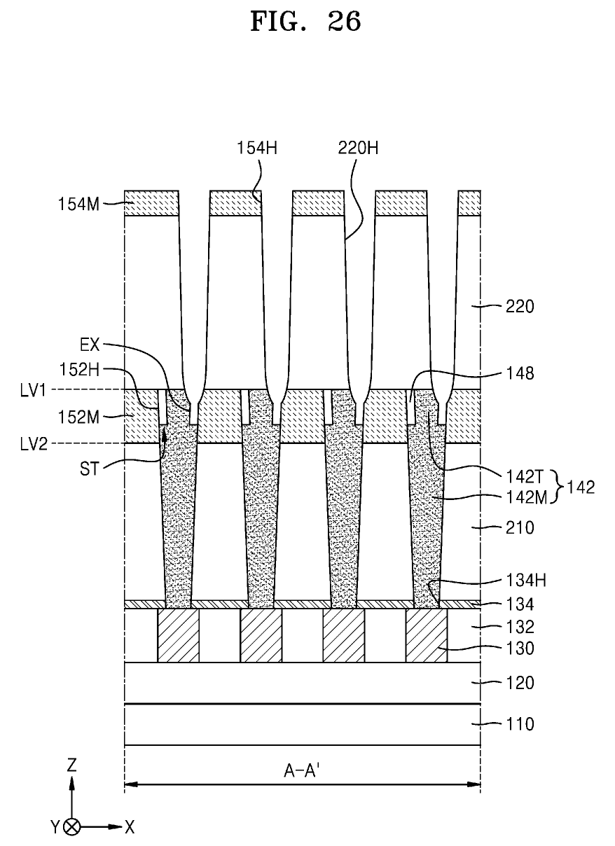

Referring to FIG. 26, an etching process for removing a portion of the insulating skin layer 148, the portion being exposed at the bottom portion of the second vertical hole 220H, may be performed. A portion of the insulating skin layer 148, vertically overlapping the second vertical hole 220H, may be removed, and an extended space EX may be formed.

In some implementations, the extended space EX may be formed by removing the entire thickness of a portion of the insulating skin layer 148, the portion vertically overlapping the second vertical hole 220H, and the edge of the top surface of the first main electrode portion 142M may be exposed at a bottom portion of the extended space EX.

In some implementations, the extended space EX may be formed by a dry etching process having anisotropic etching characteristics or directional etching characteristics, the extended space EX may be arranged at a lower vertical level than the second vertical hole 220H, at a position vertically overlapping the second vertical hole 220H. In some implementations, the extended space EX may be formed by an etching process using etching conditions including an etch selectivity with respect to the first electrode layer 142, and in an etching process for forming the extended space EX, the first electrode layer 142 may not be removed or may be hardly removed.

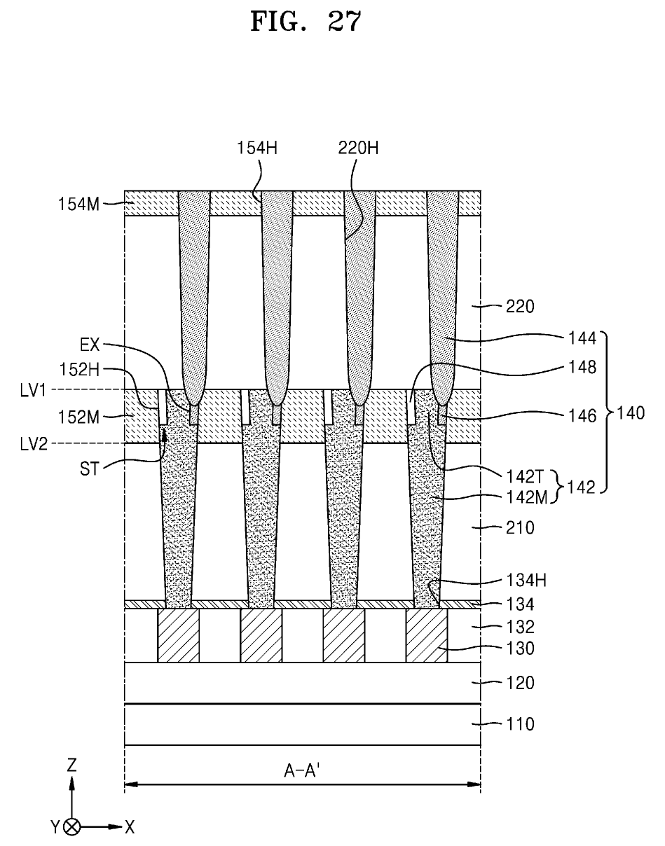

Referring to FIG. 27, the second electrode layer 144 may be formed in the second vertical hole 220H and the second opening 154H by using a conductive material. In a process for forming the second electrode layer 144, the conductive material may also be filled in the extended space EX that may communicate with the bottom portion of the second vertical hole 220H, and the conductive skin layer 146 may be formed in the extended space EX.

In some implementations, the conductive skin layer 146 may be arranged in the extended space EX to cover a portion of the side wall of the first electrode top portion 142T, and the remaining portion of the side wall of the first electrode top portion 142T, which is not covered by the conductive skin layer 146, may be covered by the insulating skin layer 148.

In some implementations, the second electrode layer 144 and the conductive skin layer 146 may be formed by using the same material, and the second electrode layer 144 and the conductive skin layer 146 may be integrally connected to each other. Because the conductive skin layer 146 is arranged on the side wall of the first electrode layer 142 (for example, the side wall of the first electrode top portion 142T), at a position vertically overlapping the second electrode layer 144, a sufficiently large area of contact between the second electrode layer 144 and the first electrode layer 142 may be secured (for example, the sum of the area of contact between the second electrode layer 144 and the first electrode layer 142 and the area of contact between the conductive skin layer 146 and the first electrode layer 142 may be sufficiently large).

Referring to FIGS. 28A, 28B, and 28C, a mask pattern may be formed on the second supporter layer 154M and the top surface of the second electrode layer 144, and a portion of the second supporter layer 154M may be removed by using the mask pattern to form the second supporter pattern 154. The second supporter pattern 154 may include a second connection opening 154H2, and the second connection opening 154H2 may be arranged to communicate with four second openings 154H.

Afterwards, the second connection opening 154H2 may extend in the vertical direction (Z) by removing a portion of the second mold insulating layer 220, the portion being exposed at a bottom portion of the second connection opening 154H2. After removing the portion of the second mold insulating layer 220, the first supporter pattern 152 may be formed by removing a portion of the first supporter layer 152M, the portion being exposed at the bottom portion of the second connection opening 154H2. The first supporter pattern 152 may include a first connection opening 152H2 arranged at a position that is at least partially vertically overlapping the second connection opening 154H2, and the first connection opening 152H2 may be arranged to communicate with four first openings 152H.

Afterwards, the first connection opening 152H2 may extend in the vertical direction (Z) by removing a portion of the first mold insulating layer 210, the portion being exposed at a bottom portion of the first connection opening 152H2.

Afterwards, the first mold insulating layer 210 and the second mold insulating layer 220 may be removed. In some implementations, a process of removing the first mold insulating layer 210 and the second mold insulating layer 220 may be an etching process using an etchant including ammonium bifluoride (NH₄F), hydrofluoric acid (HF), and water.

In the process for removing the first mold insulating layer 210 and the second mold insulating layer 220, the first supporter pattern 152 and the second supporter pattern 154 may not be removed, and two adjacent first electrode layers 142 may be connected and supported by the first supporter pattern 152. In addition, two adjacent second electrode layers 144 may be connected and supported by the second supporter pattern 154.

In some implementations, in the process for removing the first mold insulating layer 210 and the second mold insulating layer 220, a portion of the insulating skin layer 148, arranged in the first connection opening 152H2, may also be removed. However, the present disclosure is not limited thereto.

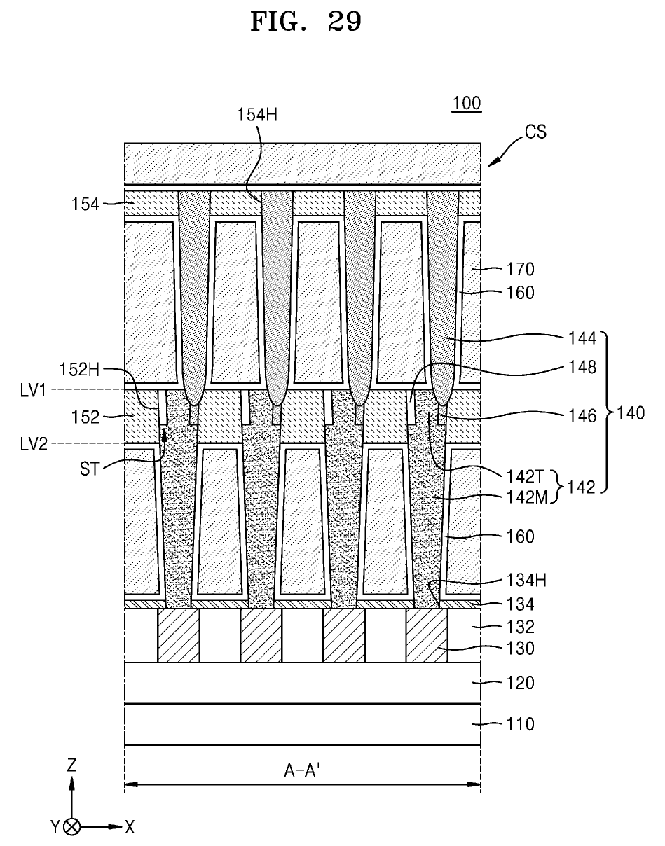

Referring to FIG. 29, the capacitor dielectric layer 160 may be conformally formed on exposed surfaces of the first electrode layer 142, the second electrode layer 144, and the conductive skin layer 146. In this case, the capacitor dielectric layer 160 may also be formed on exposed surfaces of the etch stop layer 134, the first supporter pattern 152, and the second supporter pattern 154.

Afterwards, the upper electrode 170 covering the capacitor dielectric layer 160 may be formed.

According to the method of manufacturing the semiconductor device 100 according to some implementations described above, a trimming process for reducing the width of the side wall of the first electrode material layer 142L may be performed, and accordingly, a sufficient separation distance between the first electrode layer 142 and the adjacent second electrode layer 144 may be secured. In addition, after the trimming process, the insulating skin layer 148 is formed on the side wall of the first electrode layer 142, a portion of the insulating skin layer 148 is removed, and then, in a process of forming the second electrode layer 144, the conductive skin layer 146 is formed in a space from which the insulating skin layer 148 has been removed, and thus, a sufficient area of contact between the second electrode layer 144 and the first electrode layer 142 (with the conductive skin layer 146 therebetween) may be secured. Therefore, the semiconductor device 100 may have excellent electrical characteristics.

In some implementations, after the process described with reference to FIGS. 28A to 28C, the stopper layer 156 (see FIG. 13) may be formed, and then, the process described with reference to FIGS. 24 to 29 may be performed. In this case, the semiconductor device 100C described with reference to FIG. 13 may be formed.

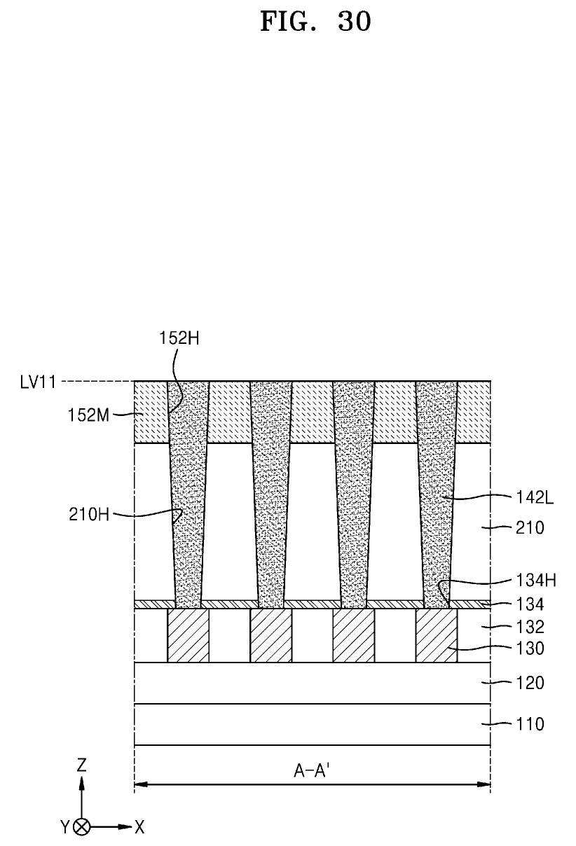

FIGS. 30 to 36 are cross-sectional views illustrating a method of manufacturing the semiconductor device 100A according to a process sequence, according to some implementations.

Referring to FIG. 30, the lower structure 120 may be formed on the top surface of the substrate 110, and the landing pad 130 and the node isolation insulating layer 132 surrounding the side wall of the landing pad 130 may be formed on the lower structure 120. Afterwards, the etch stop layer 134, the first mold insulating layer 210, and the first supporter layer 152M may be sequentially formed on the landing pad 130 and the node isolation insulating layer 132.

Afterwards, a mask pattern may be formed on the first supporter layer 152M, the first opening 152H passing through the first supporter layer 152M may be formed by using the mask pattern, and then, the first vertical hole 210H passing through the first mold insulating layer 210 may be formed. The first electrode material layer 142L may be formed in the first opening 152H and the first vertical hole 210H.

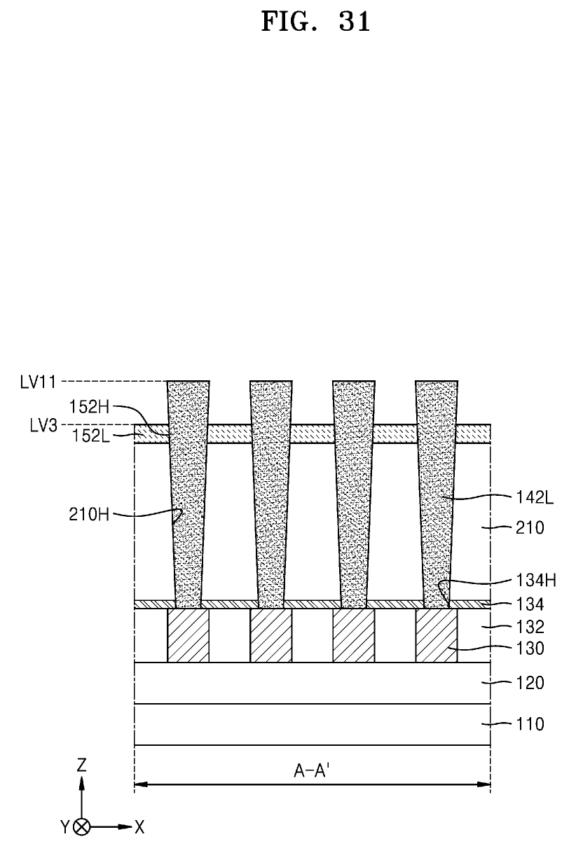

Referring to FIG. 31, the height of the first supporter layer 152M may be reduced by performing an etch-back process on an upper side of the first supporter layer 152M. In some implementations, the top surface of the first supporter layer 152M may be arranged at the third vertical level LV3 that is lower than the first reference vertical level LV11. The first supporter layer 152M whose height is reduced as a result of the etch-back process may be referred to as the lower supporter pattern 152L.

In some implementation, the etch-back process for the first supporter layer 152M may be an etching process using etching conditions including an etch selectivity with respect to the first electrode material layer 142L. While the etch-back process for the first supporter layer 152M is being performed, the first electrode material layer 142L may not be removed or only a negligible amount may be removed. As a result of the etching process, the top surface of the first electrode material layer 142L may be arranged at the first reference vertical level LV11 and may protrude beyond the top surface of the first supporter layer 152M.

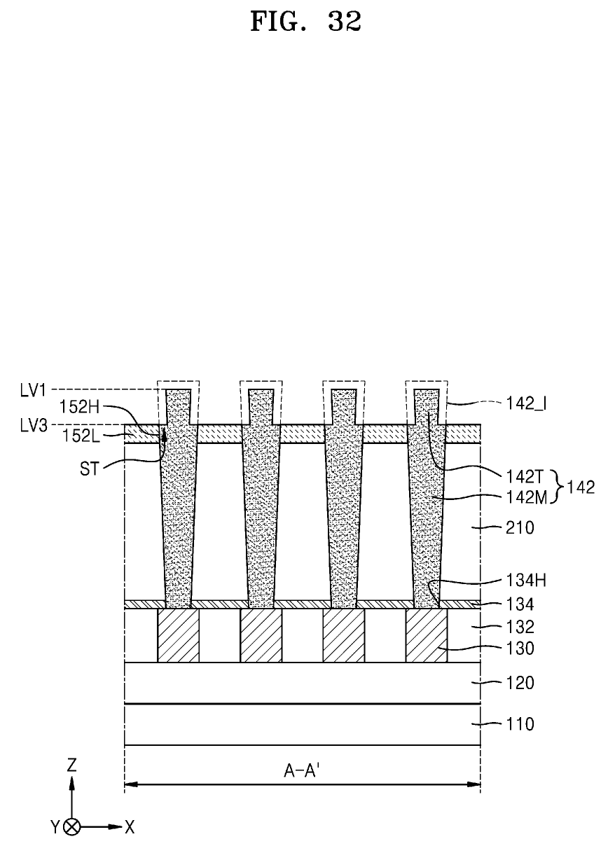

Referring to FIG. 32, a portion of the first electrode material layer 142L may be removed from the surface 142_I of the first electrode material layer 142L by performing a trimming process on the first electrode material layer 142L. In some implementations, the trimming process may include an isotropic dry etching or wet etching process.

In some implementations, as a result of the trimming process for the first electrode material layer 142L, the first portion of the first electrode material layer 142L (i.e., the first electrode top portion 142T), arranged at a higher level than the top surface of the lower supporter pattern 152L, may have a smaller width than the second portion of the first electrode material layer 142L (i.e., the first main electrode portion 142M), arranged at a lower level than or the same level as the top surface of the lower supporter pattern 152L. As a result of the trimming process for the first electrode material layer 142L, the step ST may be formed at a boundary between the first main electrode portion 142M and the first electrode top portion 142T.

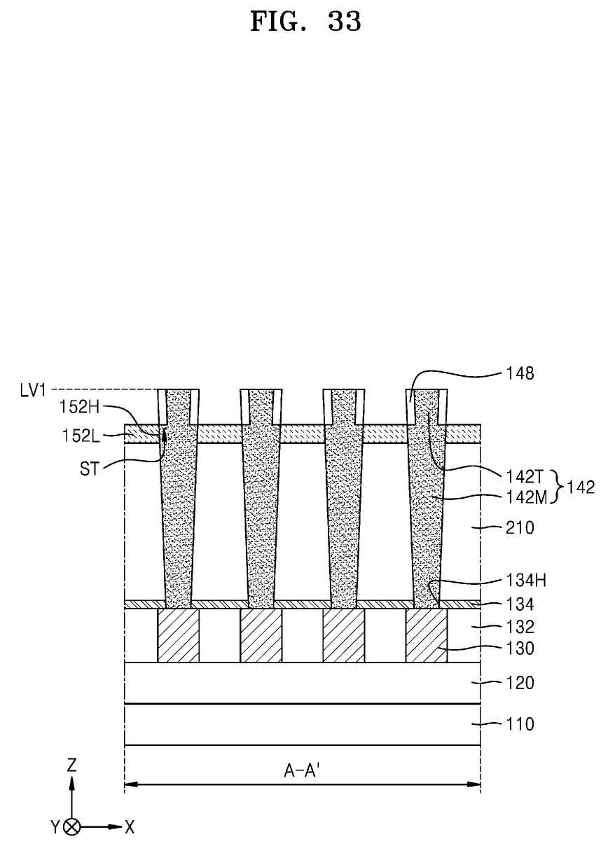

Referring to FIG. 33, an insulating layer is formed on the first electrode top portion 142T and the top surface of the lower supporter pattern 152L, and the insulating skin layer 148 may remain only on the side wall of the first electrode top portion 142T by performing an anisotropic etching process on the insulating layer.

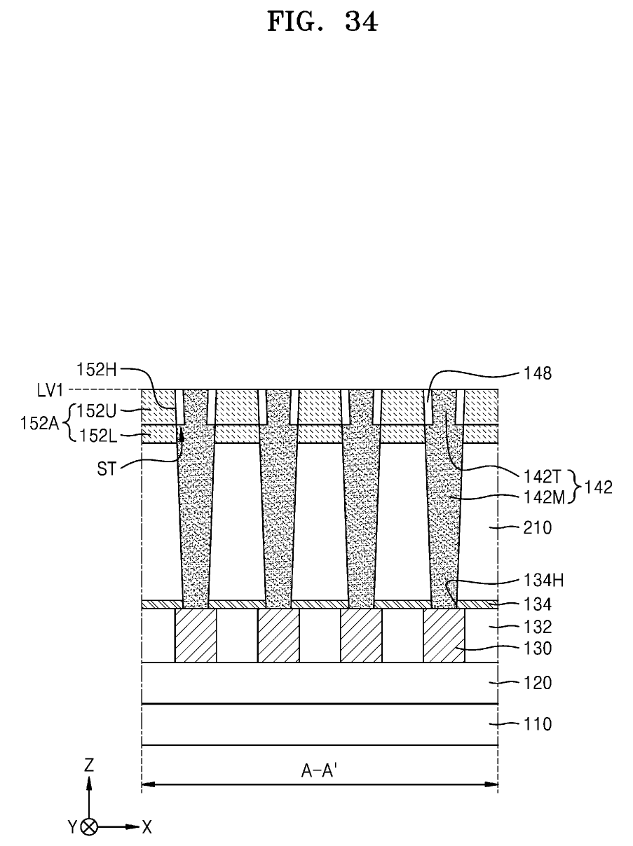

Referring to FIG. 34, the upper supporter pattern 152U may be formed on the top surface of the lower supporter pattern 152L and the side wall of the insulating skin layer 148. The top surface of the upper supporter pattern 152U may be coplanar with the top surface of the insulating skin layer 148 and the top surface of the first electrode top portion 142T. The upper supporter pattern 152U and the lower supporter pattern 152L may be collectively referred to as the first supporter pattern 152A.

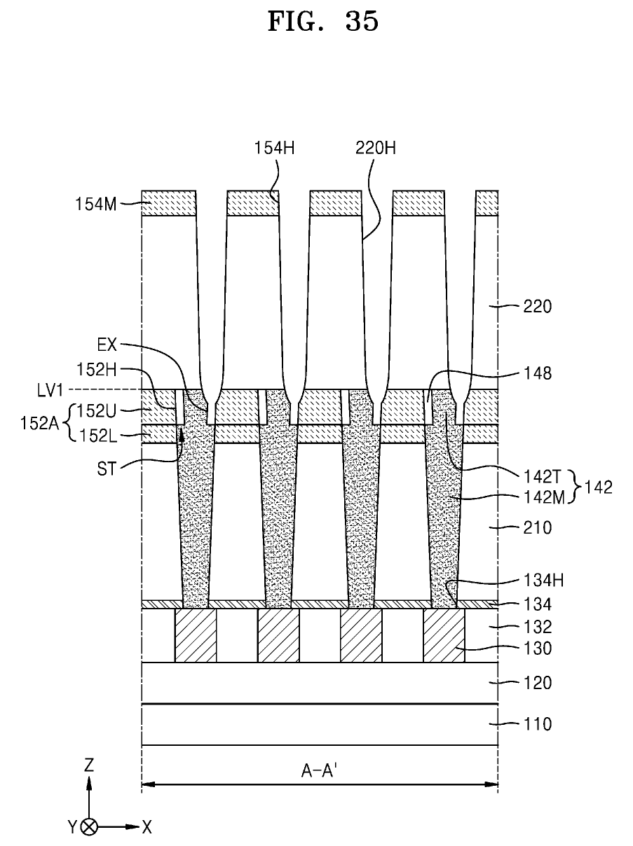

Referring to FIG. 35, the second mold insulating layer 220 and the second supporter layer 154M may be formed on the first supporter pattern 152A, the first electrode layer 142, and the top surface of the insulating skin layer 148. Afterwards, a mask pattern may be formed on the second supporter layer 154M, and the second opening 154H passing through the second supporter layer 154M and the second vertical hole 220H passing through the second mold insulating layer 220 may be formed by using the mask pattern.

Afterwards, an etching process for removing a portion of the insulating skin layer 148, the portion being exposed at the bottom portion of the second vertical hole 220H, may be performed, and the extended space EX may be formed by removing a portion of the insulating skin layer 148, the portion vertically overlapping the second vertical hole 220H.

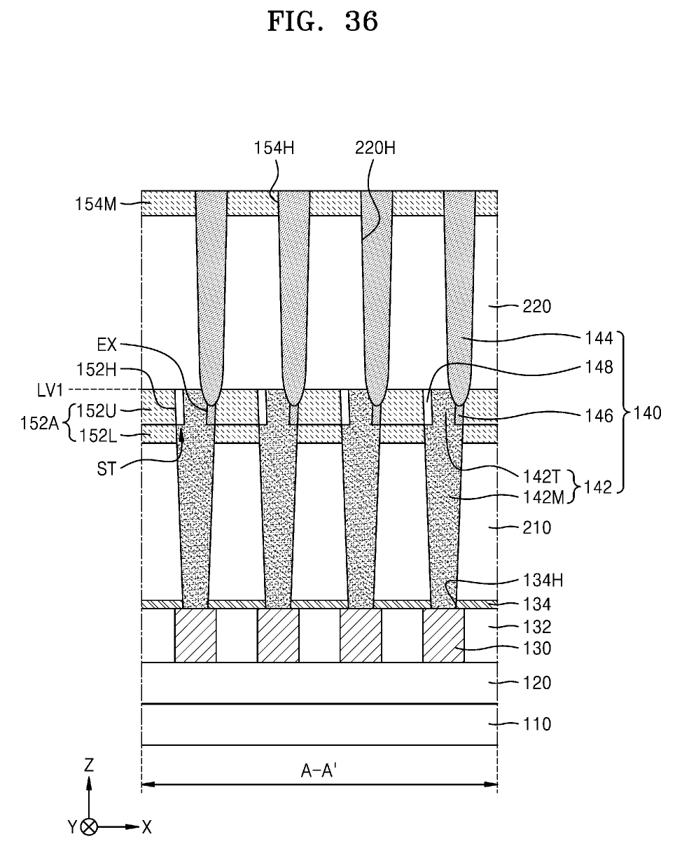

Referring to FIG. 36, the second electrode layer 144 may be formed in the second vertical hole 220H and the second opening 154H by using a conductive material. In a process for forming the second electrode layer 144, the conductive material may also be filled in the extended space EX that may communicate with the bottom portion of the second vertical hole 220H, and the conductive skin layer 146 may be formed in the extended space EX.

Afterwards, the first mold insulating layer 210 and the second mold insulating layer 220 may be removed by performing the processes described with reference to FIGS. 28A to 28C.

Referring to FIGS. 8 and 9 again, the capacitor dielectric layer 160 may be conformally formed on exposed surfaces of the first electrode layer 142, the second electrode layer 144, and the conductive skin layer 146, and the upper electrode 170 covering the capacitor dielectric layer 160 may be formed.

The semiconductor device 100A may be completely formed by performing the processes described above.

In some implementations, after the process described with reference to FIG. 34, the stopper layer 156 (see FIG. 14) may be formed, and then, the process described with reference to FIGS. 35 and 36 may be performed. In this case, the semiconductor device 100D described with reference to FIG. 14 may be formed.

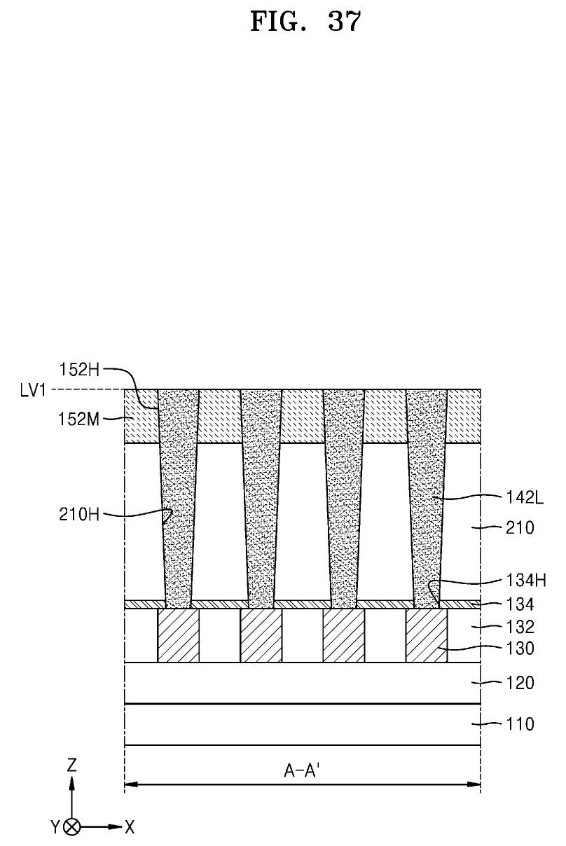

FIGS. 37 to 42 are cross-sectional views illustrating a method of manufacturing the semiconductor device 100B according to a process sequence, according to some implementations.

Referring to FIG. 37, by performing the process described with reference to FIG. 30, the first electrode material layer 142L may be formed in the first opening 152H in the first supporter layer 152M and the first vertical hole 210H in the first mold insulating layer 210.

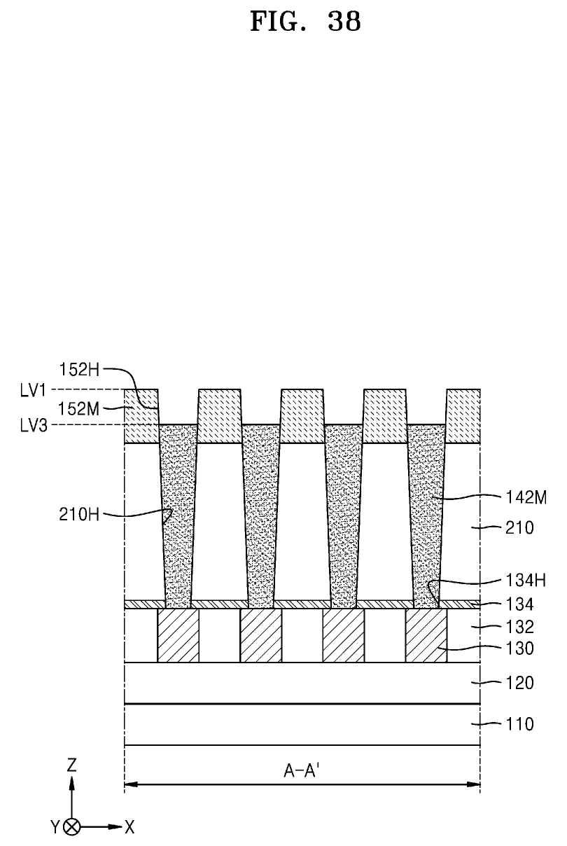

Referring to FIG. 38, the height of the first electrode material layer 142L may be reduced by performing an etch-back process on the upper side of the first electrode material layer 142L. In some implementations, the top surface of the first supporter layer 152M may be arranged at the first vertical level LV1, and the top surface of the first electrode material layer 142L may be arranged at the third vertical level LV3 lower than the first vertical level LV1. The first electrode material layer 142L whose height is reduced as a result of the etch-back process may be referred to as the first main electrode portion 142M.

In some implementations, the etch-back process for the first electrode material layer 142L may be an etching process using etching conditions including an etch selectivity with respect to the first supporter layer 152M. While the etch-back process for the first electrode material layer 142L is being performed, the first supporter layer 152M may not be removed or only a negligible amount may be removed. As a result of the etching process, a portion of an inner wall of the first opening 152H in the first supporter layer 152M may be arranged at a higher vertical level than the top surface of the first main electrode portion 142M, and the portion of the inner wall of the first opening 152H in the first supporter layer 152M may not be covered by the first main electrode portion 142M and may be exposed.

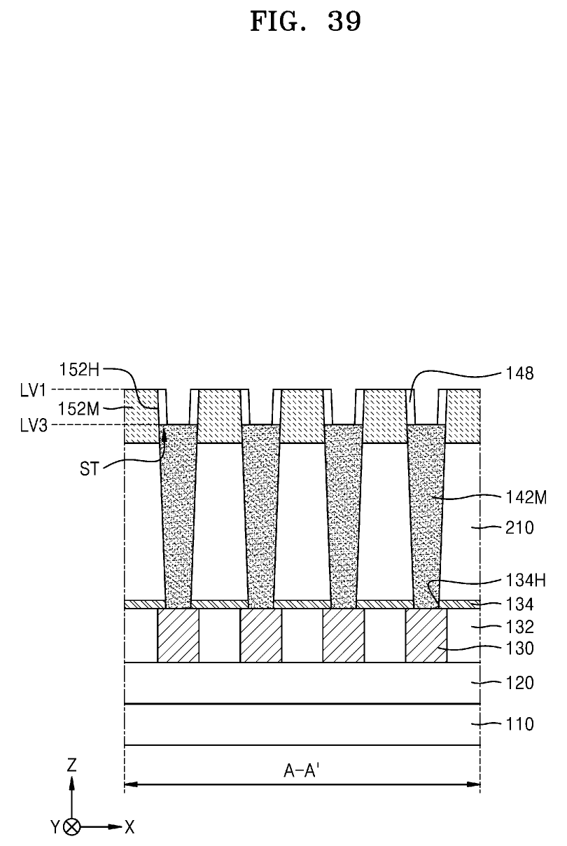

Referring to FIG. 39, an insulating layer may be formed on the top surface of the first supporter layer 152M, the inner wall of the first opening 152H in the first supporter layer 152M, and the top surface of the first main electrode portion 142M, and the insulating skin layer 148 may remain on the inner wall of the first opening 152H by performing an anisotropic etching process on the insulating layer.

In some implementations, the insulating skin layer 148 may be arranged on the edge of the top surface of the first main electrode portion 142M, and the top surface of the insulating skin layer 148 may be coplanar with the top surface of the first supporter layer 152M.

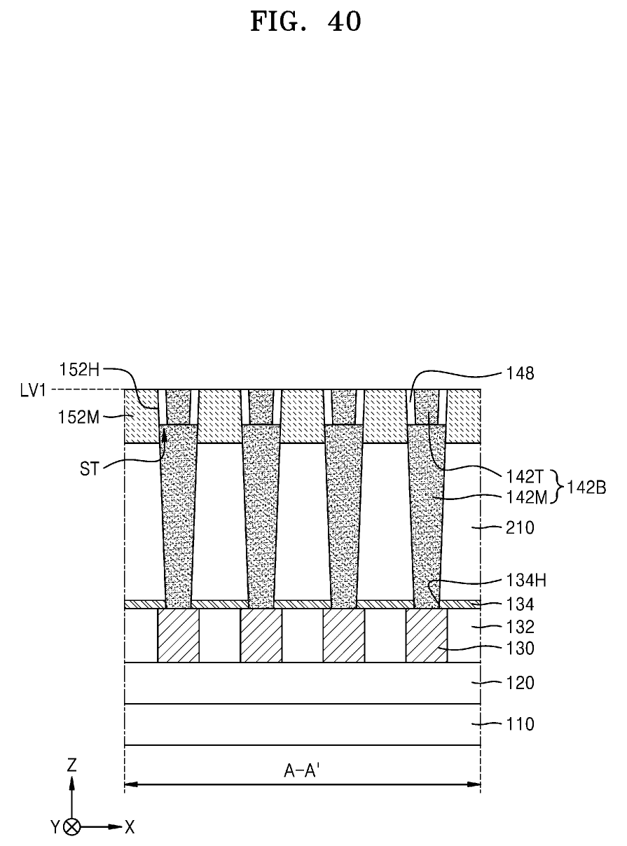

Referring to FIG. 40, the first electrode top portion 142T may be formed to fill the first opening 152H. In some implementations, the first electrode top portion 142T may be arranged on the top surface of the first main electrode portion 142M and the side wall of the insulating skin layer 148, and the top surface of the first electrode top portion 142T may be coplanar with the top surface of the first supporter layer 152M.

In some implementations, the first electrode top portion 142T may be formed by using a CVD process, an MOCVD process, an ALD process, or an MOALD process.

In some implementations, the top surface of the first main electrode portion 142M may have the first width w1 (see FIG. 11), and the bottom surface of the first electrode top portion 142T may have the second width w2 (see FIG. 11) smaller than the first width w1. Because the first electrode top portion 142T is formed while the insulating skin layer 148 is formed on the inner wall of the first opening 152H, the step ST may be formed at a boundary between the first main electrode portion 142M and the first electrode top portion 142T. In this regard, the first main electrode portion 142M and the first electrode top portion 142T may be collectively referred to as the first electrode layer 142B.

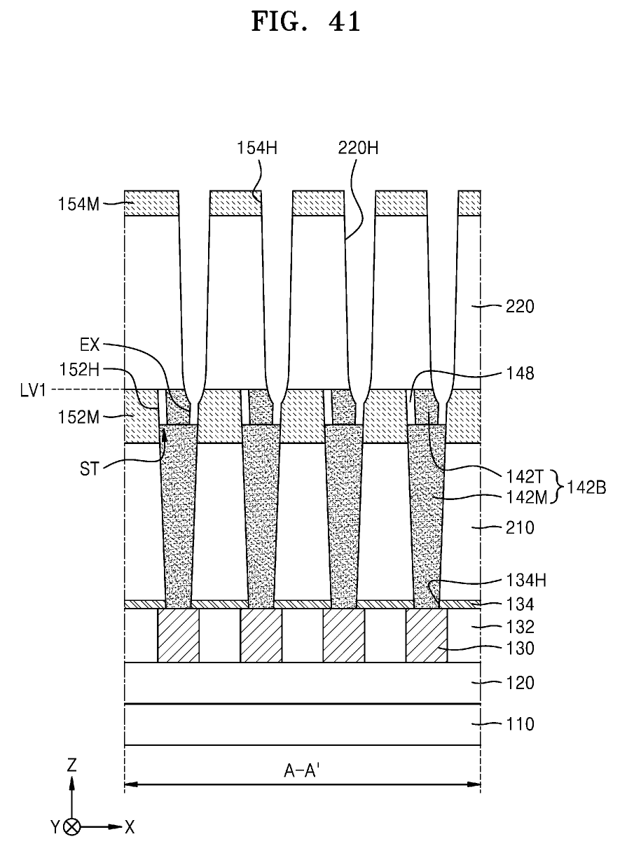

Referring to FIG. 41, the second mold insulating layer 220 and the second supporter layer 154M may be formed on the first supporter layer 152M, the first electrode top portion 142T, and the top surface of the insulating skin layer 148. Afterwards, a mask pattern may be formed on the second supporter layer 154M, and the second opening 154H passing through the second supporter layer 154M and the second vertical hole 220H passing through the second mold insulating layer 220 may be formed by using the mask pattern.

Afterwards, an etching process for removing a portion of the insulating skin layer 148, the portion being exposed at the bottom portion of the second vertical hole 220H, may be performed, and the extended space EX may be formed by removing a portion of the insulating skin layer 148, the portion vertically overlapping the second vertical hole 220H.

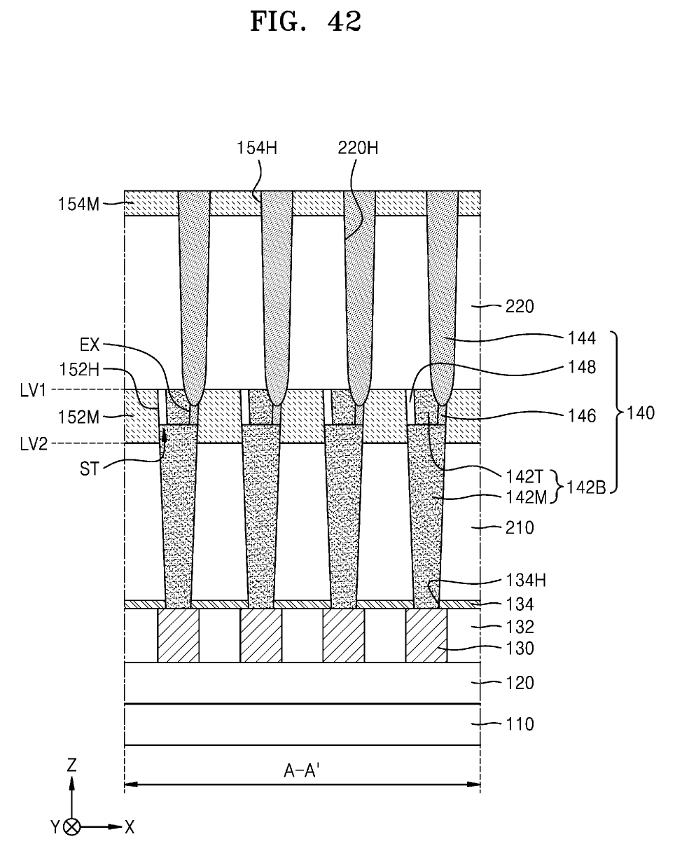

Referring to FIG. 42, the second electrode layer 144 may be formed in the second vertical hole 220H and the second opening 154H by using a conductive material. In a process for forming the second electrode layer 144, the conductive material may also be filled in the extended space EX that communicates with the bottom portion of the second vertical hole 220H, and the conductive skin layer 146 may be formed in the extended space EX.

Afterwards, the first mold insulating layer 210 and the second mold insulating layer 220 may be removed by performing the processes described with reference to FIGS. 28A to 28C.

Referring to FIGS. 10 and 11 again, the capacitor dielectric layer 160 may be conformally formed on exposed surfaces of the first electrode layer 142B, the second electrode layer 144, and the conductive skin layer 146, and the upper electrode 170 covering the capacitor dielectric layer 160 may be formed.

The semiconductor device 100B may be completely formed by performing the processes described above.

In some implementations, after the process described with reference to FIG. 40, the stopper layer 156 (see FIG. 15) may be formed, and then, the process described with reference to FIGS. 41 and 42 may be performed. In this case, the semiconductor device 100E described with reference to FIG. 15 may be formed.

According to some aspects of the present disclosure, a method of manufacturing a semiconductor device includes forming, on a substrate, a first mold insulating layer having a first vertical hole, forming, in the first vertical hole in the first mold insulating layer, a first electrode layer including a first main electrode portion and a first electrode top portion that is on the first main electrode portion with a step defined therebetween and is integrally connected to the first main electrode portion, forming an insulating skin layer disposed outside a periphery of a side wall of the first electrode top portion of the first electrode layer, forming a second mold insulating layer having a second vertical hole, on the first mold insulating layer, the first electrode layer, and the insulating skin layer, forming an extended space by removing a portion of the insulating skin layer, the portion being exposed at a bottom portion of the second vertical hole, and forming a second electrode layer in the second vertical hole in the second mold insulating layer and forming a conductive skin layer in the extended space.

In some implementations, the method may further include, before the forming of the first electrode layer, forming, on a top surface of the first mold insulating layer, a supporter pattern having a first opening, and the forming of the first electrode layer may include forming the first electrode layer such that an upper side of the first main electrode portion and the first electrode top portion are arranged in the first opening in the supporter pattern.

In some implementations, the forming of the first electrode layer may include forming the first main electrode portion in the first vertical hole in the first mold insulating layer and the first opening in the supporter pattern, performing an etch-back process on an upper side of the supporter pattern to reduce a height of the supporter pattern and expose an upper side of a side wall of the first main electrode portion, and performing an etching process on the upper side of the side wall of the first main electrode portion to form the step on the upper side of the side wall of the first main electrode portion.

In some implementations, the method may further include, after the forming of the insulating skin layer disposed outside a periphery of the side wall of the first electrode top portion, forming a second supporter layer on a side wall of the insulating skin layer and a top surface of the supporter pattern whose height is reduced.

In some implementations, the forming of the first electrode layer may include forming the first main electrode portion in the first vertical hole in the first mold insulating layer and in the first opening in the supporter pattern, performing an etch-back process on the upper side of the first main electrode portion to reduce a height of the first main electrode portion and expose an upper side of the first opening in the supporter pattern, forming the insulating skin layer on a side wall of the upper side of the first opening in the supporter pattern, and forming, on a top surface of the first main electrode portion, the first electrode top portion filling the upper side of the first opening in the supporter pattern.

In some implementations, the method may further include, after the forming of the insulating skin layer, forming, on the first mold insulating layer, a supporter pattern to be disposed outside a periphery of the insulating skin layer.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various changes in form and details may be made therein without departing from the spirit and scope of the following claims.

What is claimed is:

1. A semiconductor device comprising:
a first electrode layer on a substrate, the first electrode layer comprising:
a first main electrode portion extending in a first direction perpendicular to a top surface of the substrate; and
a first electrode top portion on the first main electrode portion, wherein a step is defined between the first main electrode portion and the first electrode top portion, wherein the first electrode top portion is connected to the first main electrode portion;
a second electrode layer on the first electrode layer and extending in the first direction;
an insulating skin layer on a first portion of a side wall of the first electrode top portion and being in contact with a top surface of the first main electrode portion;
a supporter pattern on a side wall of the insulating skin layer;
a capacitor dielectric layer on a side wall of the first electrode layer and a side wall of the second electrode layer; and
an upper electrode on the capacitor dielectric layer.

2. The semiconductor device of claim 1, further comprising a conductive skin layer on a second portion of the side wall of the first electrode top portion and being in contact with a bottom surface of the second electrode layer.

3. The semiconductor device of claim 2, wherein the supporter pattern comprises an opening, and
the first electrode top portion, the conductive skin layer, and the insulating skin layer are in the opening.

4. The semiconductor device of claim 2, wherein, in a plan view, the conductive skin layer is disposed outside a periphery of a first portion of the first electrode top portion, and
in a plan view, the insulating skin layer is disposed outside a periphery of a second portion of the first electrode top portion.

5. The semiconductor device of claim 2, wherein a bottom surface of the conductive skin layer is coplanar with a bottom surface of the insulating skin layer.

6. The semiconductor device of claim 1, wherein the top surface of the first main electrode portion has a first width in a horizontal direction,
wherein a bottom surface of the first electrode top portion has a second width that is less than the first width in the horizontal direction, and
wherein the step is defined between an edge of the top surface of the first main electrode portion and the side wall of the first electrode top portion.

7. The semiconductor device of claim 2, wherein the conductive skin layer overlaps the second electrode layer in the first direction.

8. The semiconductor device of claim 2, wherein the first main electrode portion and the first electrode top portion are integrally connected to each other, and
wherein a bottom portion of the second electrode layer is integrally connected to the conductive skin layer.

9. The semiconductor device of claim 1, wherein a bottom surface of the second electrode layer is at a lower vertical level than a top surface of the first electrode top portion.

10. The semiconductor device of claim 1, wherein a bottom portion of the second electrode layer is in contact with the supporter pattern.

11. The semiconductor device of claim 1, wherein the first electrode top portion defines a first center line that passes through a center of a top surface of the first electrode top portion and extends in the first direction, and the second electrode layer defines a second center line that passes through a center of a bottom surface of the second electrode layer and extends in the first direction, wherein the first center line is spaced apart from the second center line in a second direction perpendicular to the first direction.

12. The semiconductor device of claim 1, wherein the supporter pattern comprises a lower supporter pattern and an upper supporter pattern on a top surface of the lower supporter pattern, and
wherein a bottom surface of the upper supporter pattern is coplanar with a bottom surface of the insulating skin layer.

13. The semiconductor device of claim 1, further comprising a stopper layer on a top surface of the first electrode top portion, a top surface of the insulating skin layer, and a top surface of the supporter pattern, wherein a bottom portion of the second electrode layer passes through the stopper layer.

14. A semiconductor device comprising:
a first electrode layer on a substrate and extending in a first direction perpendicular to a top surface of the substrate;
a second electrode layer on the first electrode layer and extending in the first direction;
a supporter pattern disposed outside a periphery of an upper side of the first electrode layer;
a conductive skin layer disposed between a first portion of an upper side wall of the first electrode layer and the supporter pattern and being in contact with a bottom surface of the second electrode layer;
an insulating skin layer disposed between a second portion of the upper side wall of the first electrode layer and the supporter pattern;
a capacitor dielectric layer on a side wall of the first electrode layer and a side wall of the second electrode layer; and
an upper electrode on the capacitor dielectric layer.

15. The semiconductor device of claim 14, wherein a bottom surface of the conductive skin layer is coplanar with a bottom surface of the insulating skin layer.

16. The semiconductor device of claim 14, wherein the conductive skin layer overlaps the second electrode layer in the first direction, and
wherein a bottom portion of the second electrode layer is integrally connected to the conductive skin layer.

17. The semiconductor device of claim 14, wherein the first electrode layer comprises:
a first main electrode portion extending in the first direction; and
a first electrode top portion on the first main electrode portion and integrally connected to the first main electrode portion,
wherein a step is defined between the first main electrode portion and the first electrode top portion.

18. The semiconductor device of claim 17, wherein the bottom surface of the second electrode layer is at a lower vertical level than a top surface of the first electrode top portion, and
wherein a bottom portion of the second electrode layer is in contact with the supporter pattern.

19. A semiconductor device comprising:
a plurality of lower electrodes on a substrate;
a capacitor dielectric layer on side walls of the plurality of lower electrodes; and
an upper electrode on the capacitor dielectric layer,
wherein each of the plurality of lower electrodes comprises:
a first electrode layer comprising:
a first main electrode portion extending in a first direction perpendicular to a top surface of the substrate; and
a first electrode top portion on the first main electrode portion, wherein a step is defined between the first main electrode portion and the first electrode top portion, wherein the first electrode top portion is integrally connected to the first main electrode portion;
a second electrode layer on the first electrode layer and extending in the first direction; and
an insulating skin layer on a first portion of a side wall of the first electrode top portion and being in contact with a top surface of the first main electrode portion,
wherein the top surface of the first main electrode portion has a first width in a horizontal direction,
wherein a bottom surface of the first electrode top portion has a second width that is less than the first width in the horizontal direction, and
wherein the step is defined between an edge of the top surface of the first main electrode portion and the side wall of the first electrode top portion.

20. The semiconductor device of claim 19, further comprising:
a conductive skin layer on a second portion of the side wall of the first electrode top portion and being in contact with a bottom surface of the second electrode layer; and
a supporter pattern on a side wall of the insulating skin layer and a side wall of the conductive skin layer,
wherein a top surface of the supporter pattern is coplanar with a top surface of the first electrode top portion.
